(19) United States
(12) Patent Application Publication
(10) Pub. No.: US 2017/0271451 A1
(43) Pub. Date: Sep. 21, 2017

(54) SEMICONDUCTOR DEVICE

(71) Applicant: KABUSHIKI KAISHA TOSHIBA, Tokyo (JP)

(72) Inventors: Kenichi MATSUSHITA, Nonoichi Ishikawa (JP); Norio YASUHARA, Kanazawa Ishikawa (JP); Bungo TANAKA, Nonoichi Ishikawa (JP)

(21) Appl. No.: 15/252,204

(22) Filed: Aug. 30, 2016

(30) Foreign Application Priority Data
Mar. 15, 2016 (JP) 2016051689

(51) Int. Cl. H01L 29/10; H01L 29/78; H01L 29/40; H01L 29/739; H01L 29/417; H01L 29/423

(52) U.S. Cl. CPC H01L 29/1095; H01L 29/41741; H01L 29/4236; H01L 29/407; H01L 29/7397; H01L 29/7813

(57) ABSTRACT

A semiconductor device includes a first-conductivity type first semiconductor region, a gate electrode extending inwardly of the first semiconductor region, a gate insulation layer interposed between the gate electrode and the first semiconductor region, a second-conductivity type second semiconductor region on the first semiconductor region, a first-conductivity type third semiconductor region on selected portions of second semiconductor region, a second-conductivity type fourth semiconductor region on the first semiconductor region and spaced from the second semiconductor region, a first-conductivity type fifth semiconductor region on the fourth semiconductor region, a first insulation layer on the third and fifth semiconductor regions and extending over the gate electrode, a first electrode on the first insulation layer, and a first insulation portion extending between the second and fourth semiconductor regions.

### CROSS-REFERENCE TO RELATED APPLICATION

This application is based upon and claims the benefit of priority from Japanese Patent Application No. 2016-051689, filed Mar. 15, 2016, the entire contents of which are incorporated herein by reference.

### FIELD

Embodiments described herein relate generally to a semiconductor device.

### BACKGROUND

Semiconductor devices such as a diode, a metal oxide semiconductor field effect transistor (MOSFET), and an insulated gate bipolar transistor (IGBT) are used for power conversion or the like. Reliability is preferably high in semiconductor devices.

### DESCRIPTION OF THE DRAWINGS

FIG. 1 is a plan view illustrating a semiconductor device according to a first embodiment.

FIG. 2 is a plan view illustrating the semiconductor device according to the first embodiment.

FIG. 3 is a perspective sectional view illustrating a portion A in FIG. 2.

FIG. 4 is a sectional view taken along the line B-B′ in FIG. 2.

FIG. 5 is a sectional view taken along the line C-C′ in FIG. 2.

FIG. 6 is a graph illustrating a current-voltage property of a semiconductor device according to a reference example.

FIG. 7 is a perspective sectional view illustrating a portion of a semiconductor device according to a first modification example of the first embodiment.

FIG. 8 is a perspective sectional view illustrating a portion of a semiconductor device according to a second modification example of the first embodiment.

FIG. 9 is a plan view illustrating a semiconductor device according to a third modification example of the first embodiment.

FIG. 10 is a plan view illustrating the semiconductor device according to the third modification example of the first embodiment.

FIG. 11 is a sectional view taken along the line A-A′ in FIG. 10.

FIG. 12 is a perspective sectional view illustrating a portion of a semiconductor device according to a fourth modification example of the first embodiment.

FIG. 13 is a plan view illustrating a semiconductor device according to a second embodiment.

FIG. 14 is a plan view illustrating the semiconductor device according to the second embodiment.

FIG. 15 is a sectional view taken along the line A-A′ in FIG. 14.

FIG. 16 is a plan view illustrating a semiconductor device according to a third embodiment.

FIG. 17 is a plan view illustrating the semiconductor device according to the third embodiment.

FIG. 18 is a plan view illustrating the semiconductor device according to the third embodiment.

FIG. 19 is a sectional view taken along the line A-A′ in FIG. 18.

FIG. 20 is a sectional view taken along the line B-B′ in FIG. 18.

FIG. 21 is a plan view illustrating a semiconductor device according to a first modification example of the third embodiment.

FIG. 22 is a plan view illustrating a semiconductor device according to the first modification example of the third embodiment.

FIG. 23A is a sectional view taken along the line A-A′ in FIG. 22 and FIG. 23B is a sectional view taken along the line B-B′ in FIG. 22.

FIG. 24 is a plan view illustrating a semiconductor device according to a second modification example of the third embodiment.

FIG. 25 is a plan view illustrating a semiconductor device according to the second modification example of the third embodiment.

FIG. 26A is a sectional view taken along the line A-A′ in FIG. 25 and FIG. 26B is a sectional view taken along the line B-B′ in FIG. 25.

FIG. 27 is a sectional view taken along the line C-C′ in FIG. 25.

### DETAILED DESCRIPTION

In general, according to one embodiment, a semiconductor device includes a first-conductivity type first semiconductor region, a gate electrode extending inwardly of the first semiconductor region, a gate insulation layer interposed between the gate electrode and the first semiconductor region, a second-conductivity type second semiconductor region on the first semiconductor region, a first-conductivity type third semiconductor region on selected portions of second semiconductor region, a second-conductivity type fourth semiconductor region on the first semiconductor region and spaced from the second semiconductor region, a first-conductivity type fifth semiconductor region on the fourth semiconductor region, a first insulation layer on the third and fifth semiconductor regions and extending over the gate electrode, a first electrode on the first insulation layer, and a first insulation portion extending between the second and fourth semiconductor regions.

Hereinafter, embodiments will be described with reference to the drawings.

The drawings are schematic and conceptual, and relations between the thicknesses and widths of respective portions, ratios between the sizes of the portions, and the like may not be said to be the same as the actual relations and ratios. Even in the same portions, dimensions or ratios may be sometimes different depending on the drawings.

In this disclosure, same reference numerals are given to elements which are the same as those described already and the detailed description thereof will not be repeated.

In the description of the embodiments, the XYZ rectangular coordinate system is used. A direction leading to a p type semiconductor region 4 from an n⁻ type semiconductor region 3 is referred to as the Z direction (third direction) and two directions perpendicular to the Z direction and orthogonal to each other are referred to as the X direction (second direction) and the Y direction (first direction).

In the following description, notations of n⁺, n⁻, p⁺, and p indicate relative magnitude of impurity concentration in conductivity types. That is, notation with “+” is relatively higher than notation with neither “+” or “−” in impurity concentration and notation with “−” is relatively lower than notation with neither “+” or “−” in impurity concentration.

In embodiments to be described below, a p type or an n type semiconductor region may be reversed to carry out the embodiments.

### First Embodiment

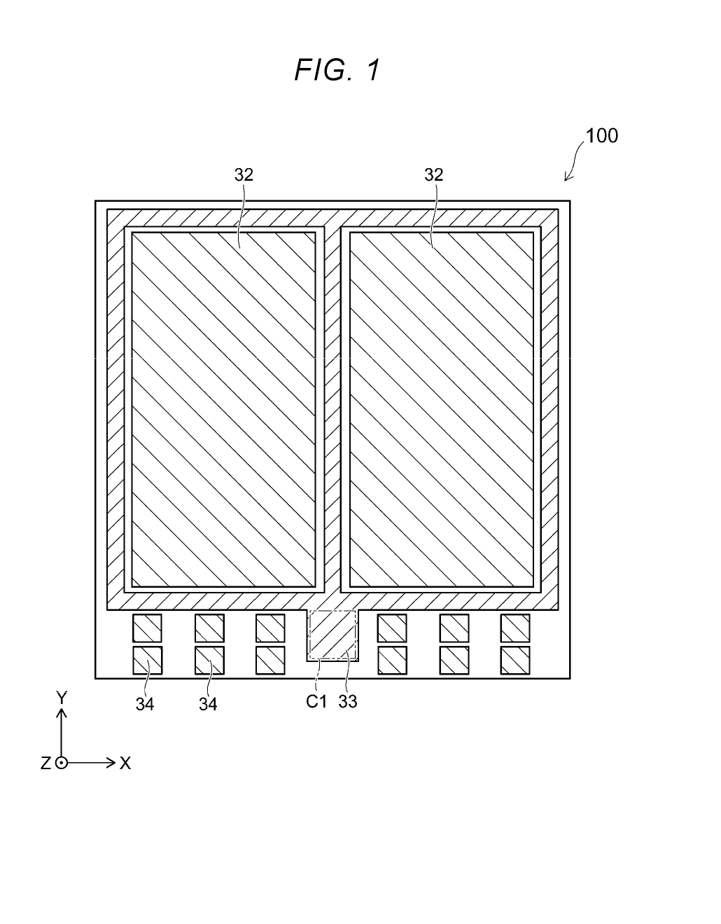

An example of a semiconductor device according to the first embodiment will be described with reference to FIGS. 1 to 5.

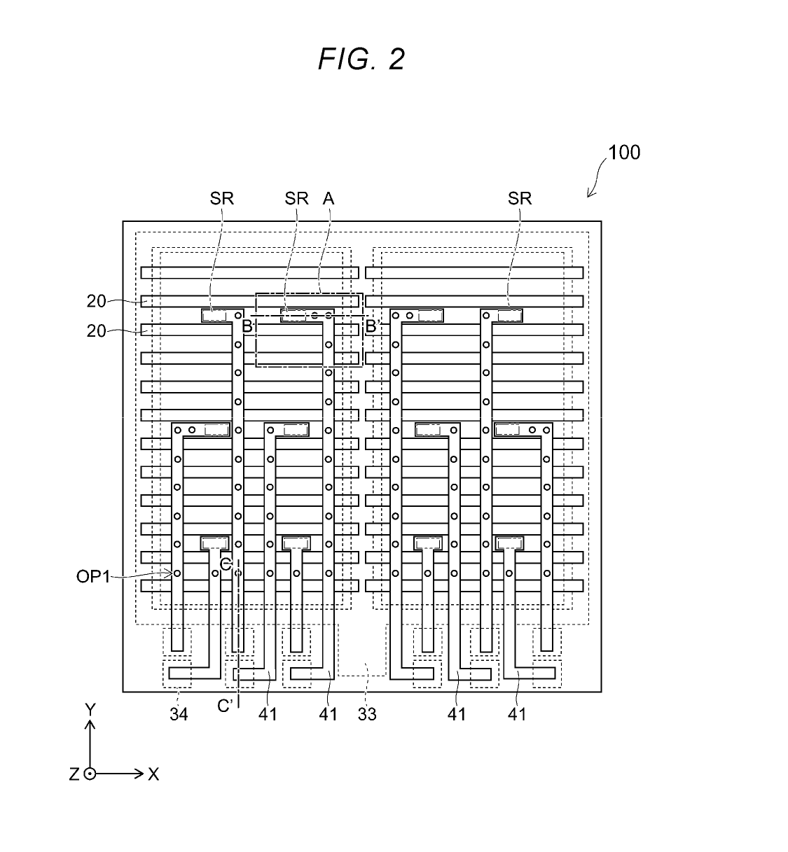

FIGS. 1 and 2 are plan views illustrating a semiconductor device 100 according to the first embodiment.

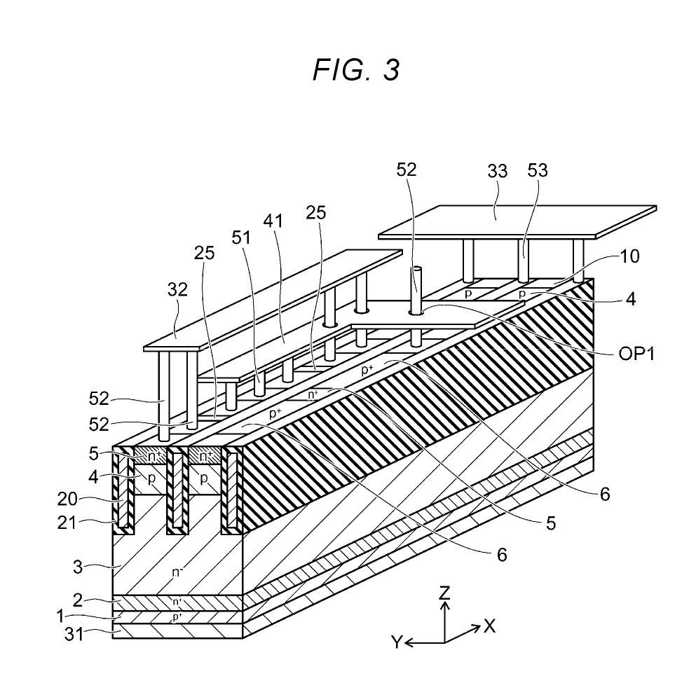

FIG. 3 is a perspective sectional view illustrating a portion A in FIG. 2.

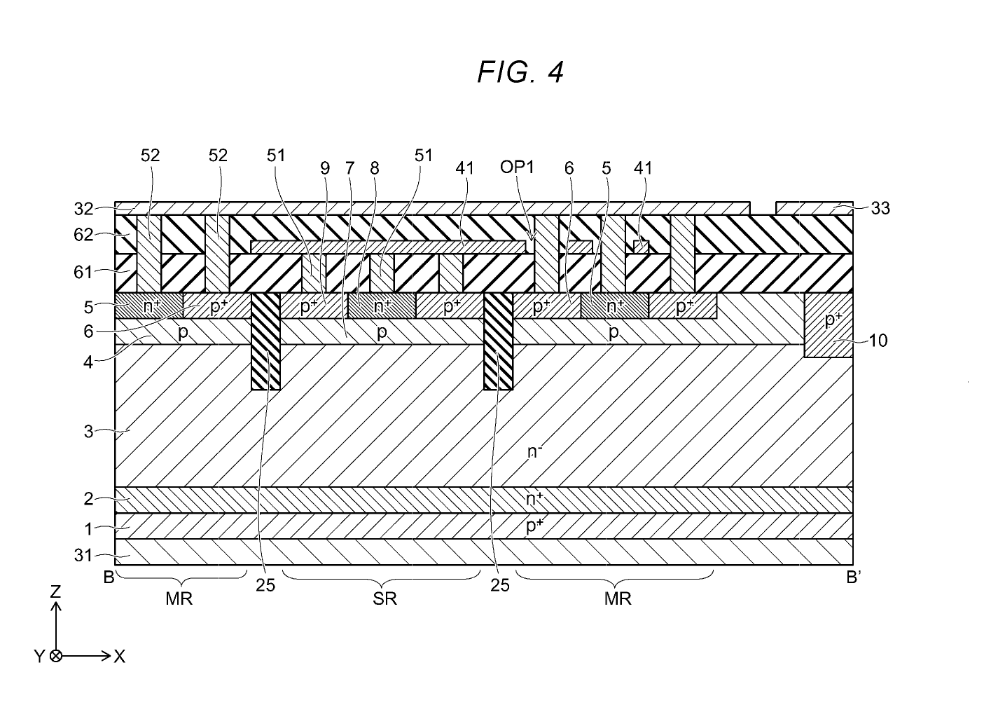

FIG. 4 is a sectional view taken along the line B-B′ in FIG. 2.

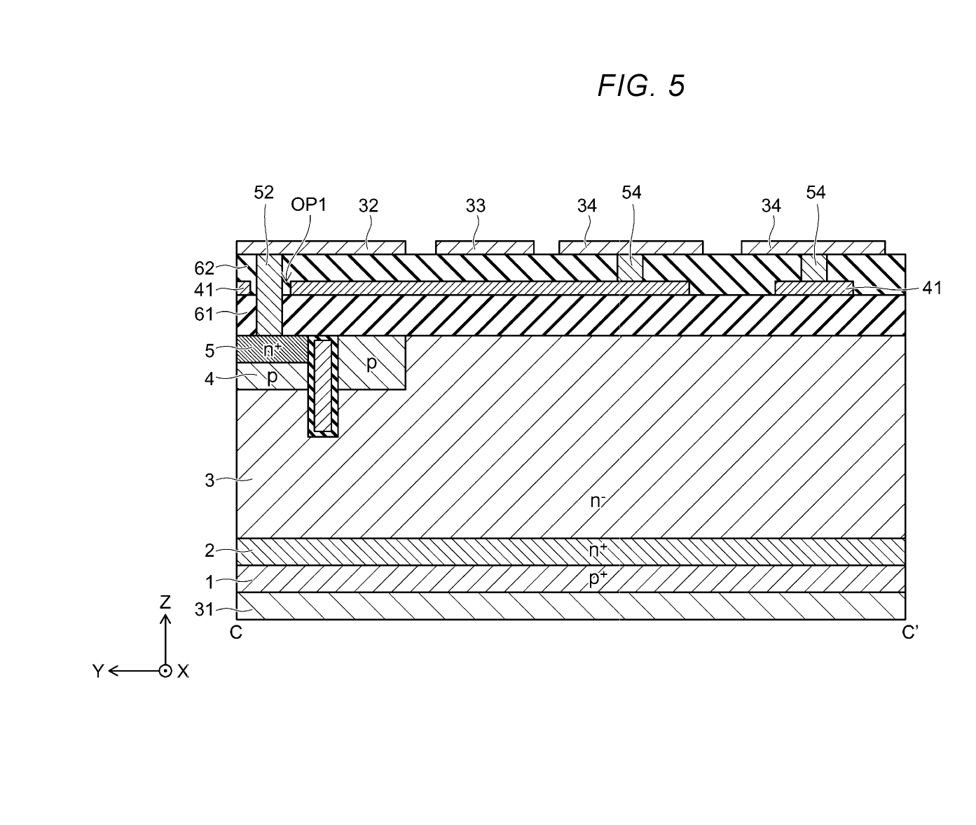

FIG. 5 is a sectional view taken along the line C-C′ in FIG. 2.

In FIG. 2, each semiconductor region, a gate insulation layer 21, insulation portions 25, and insulation layers 61 and 62 are not illustrated. Emitter pads 32, a gate wiring 33 and sense pads 34 are indicated by dotted lines.

In FIG. 3, for clarity, the insulation layers 61 and 62 are not illustrated, and only a portion of the metal layer 41, a portion of the emitter pad 32, and some of the plurality of plugs 52 are illustrated.

The semiconductor device 100 is an IGBT.

As illustrated in FIGS. 1 to 5, the semiconductor device 100 includes a p⁺ type semiconductor region 1, an n⁺ type semiconductor region 2,n n⁻ type semiconductor region 3, p type semiconductor regions 4, n⁺ type semiconductor regions 5, p⁺ type semiconductor regions 6, p type semiconductor regions 7, n⁺ type semiconductor regions 8, p⁺ type semiconductor regions 9, p⁺ type semiconductor region 10, gate electrodes 20, the gate insulation layers 21, insulation portions 25, a collector electrode 31, emitter pads 32, gate wiring 33, sense pads 34, metal layers 41, plugs 51 to 54, insulation layer 61, and insulation layer 62.

As illustrated in FIG. 1, the emitter pads 32, the gate wiring 33, and the sense pads 34 are formed on the upper surface of the semiconductor device 100, and spaced from and thus electrically isolated from each other. The emitter pads 32 are spaced apart in the X direction and each one is surrounded by the gate wiring 33. The gate wiring 33 has a pad portion C1 connectable to an external circuit. The plurality of sense pads 34 are formed along a side of, and spaced from and thus electrically isolated from, the pad portion C1.

The shapes and arrangement of the emitter pads 32, the gate wiring 33, and the sense pads 34 can be appropriately changed. Any number of sense pads 34 may be used.

Below the emitter pads 32, the gate wiring 33, and the sense pads 34, a plurality of metal layers 41 (sense wiring) are formed and are spaced from each other, as illustrated in FIG. 2.

Below the emitter pad 32 and the plurality of metal layers 41, gate electrodes 20 are formed. A plurality of gate electrodes 20 are formed below each emitter pad 32 spaced apart in the Y direction and each one extends in the X direction.

Below the emitter pad 32, a sense region SR is also partially formed. The sense region SR is located between the gate electrodes 20 in the Y direction.

A portion of each metal layer 41 is formed above a sense region SR and another portion of each metal layer 41 is formed below a sense pad 34.

As illustrated in FIG. 3, the collector electrode 31 is formed on the lower surface of the semiconductor device 100.

The p⁺ type semiconductor region 1 is formed above the collector electrode 31 and is electrically connected to the collector electrode 31.

The n⁺ type semiconductor region 2 is formed above the p⁺ type semiconductor region 1.

The n⁻ type semiconductor region 3 is formed above the n⁺ type semiconductor region 2.

The gate electrode 20 extends from within the n⁻ type semiconductor region 3 to a position above the n⁻ type semiconductor region 3 and the gate insulation layer 21 is interposed between the gate electrode 20 and the n⁻ type semiconductor region 3 and around the portion of the gate electrode 20 extending from the n⁻ type semiconductor region 3.

The p type semiconductor region 4 is formed above the n⁻ type semiconductor region 3 between portions of the gate insulation 21 on the gate electrodes 20.

The plurality of p type semiconductor regions 4 extend between the gate insulation layers 21 on adjacent gate electrodes 20 in the Y direction and each extends in the X direction.

As illustrated in FIGS. 3 and 4, the n⁺ type semiconductor regions 5 and the p⁺ type semiconductor regions 6 are selectively formed above the p type semiconductor regions 4. The n⁺ type semiconductor regions 5 and the p⁺ type semiconductor regions 6 are alternately formed on the p type semiconductor regions 4 in the X direction.

The p⁺ type semiconductor region 10 is formed above the n⁻ type semiconductor region 3 and is located below the gate wiring 33.

The insulation portions 25 are formed between some of the adjacent gate insulating layers 21 covering adjacent gate electrodes 20 of the plurality of gate electrodes 20. The insulation portion 25 extends in the Z direction and a portion of the insulation portion 25 extends into the n⁻ type semiconductor region 3. The plurality of insulation portions 25 are formed spaced apart from each other in the X direction.

As illustrated in FIG. 4, the p type semiconductor region 7 is formed above the n⁻ type semiconductor region 3 between the insulation portions 25.

The n⁺ type semiconductor region 8 and the p⁺ type semiconductor region 9 are selectively formed above the p type semiconductor region 7.

The p type semiconductor region 7, the n⁺ type semiconductor region 8, and the p⁺ type semiconductor region 9 are surrounded by gate insulation layers 21 and the insulation portions 25 and thus insulated from the p type semiconductor region 4, the n⁺ type semiconductor region 5, and the p⁺ type semiconductor region 6.

The region in which the p type semiconductor region 7, the n⁺ type semiconductor region 8, and p⁺ type semiconductor region 9 are formed is used as the sense region SR.

Hereinafter, the region in which the p type semiconductor region 4, the n⁺ type semiconductor region 5, and the p⁺ type semiconductor region 6 are formed is referred to as a main region MR.

The insulation layer 61 is formed above the n⁺ type semiconductor region 5, the p⁺ type semiconductor region 6, the n⁺ type semiconductor region 8, and the p⁺ type semiconductor region 9.

The metal layers 41 are formed above the insulation layer 61.

The plurality of plugs 51 are formed in and extend through the insulation layer 61. The n⁺ type semiconductor region 8 and p⁺ type semiconductor region 9 are connected to the metal layer 41 by the plugs 51.

The insulation layer 62 is formed above the metal layer 41 and the insulation layer 61.

The emitter pad 32, the gate wiring 33, and the sense pads 34 are formed above the insulation layer 62.

The plurality of plugs 52 are formed in and extend through the insulation layer 61 and the insulation layer 62. The n⁺ type semiconductor region 5 and the p⁺ type semiconductor region 6 are connected to the emitter pad 32 by the plugs 52.

Portions of the metal layers 41 are located above the n⁺ type semiconductor region 5 and the p⁺ type semiconductor region 6. An opening OP1 is formed in these portions of the metal layers 41 and each plug 52 is connected to the n⁺ type semiconductor region 5 or the p⁺ type semiconductor region 6 through the opening OP1.

The plurality of plugs 53 are formed in and extend through the insulation layer 61 and the insulation layer 62 as in the plugs 51 and 52. As illustrated in FIG. 3, each plug 53 connects the gate wiring 33 to the gate electrode 20.

As illustrated in FIG. 5, portions of the metal layers 41 are formed below the gate wiring 33 and below the sense pad 34.

The plug 54 is formed in the insulation layer 62 and connects each sense pad 34 to a metal layer 41. That is, the n⁺ type semiconductor region 8 and p⁺ type semiconductor region 9 are connected to the sense pad 34 by the plugs 51, the metal layers 41, and the plugs 54.

Here, an operation of the semiconductor device 100 will be described.

When a voltage equal to or greater than a threshold value is applied to the gate electrodes 20 in a state in which a positive voltage with respect to the emitter pads 32 and the sense pads 34 is applied to the collector electrode 31, the semiconductor device is turned on. At this time, channels (reverse layers) are formed in regions of the p type semiconductor regions 4 and 7 near the gate insulation layers 21. Electrons are injected from the n⁺ type semiconductor regions 5 and 8 into the n⁻ type semiconductor regions 3 through the channels and are discharged through the collector electrode 31. Holes are injected from the p⁺ type semiconductor region 1 into the n⁻ type semiconductor region 3 and are discharged through the emitter pads 32 and the sense pads 34.

Thereafter, when the voltage applied to the gate electrodes 20 is reduced to a value lower than the threshold value, the channels in the p type semiconductor regions 4 and 7 disappear and the semiconductor device is turned off.

The sense regions SR are connected to, for example, an ammeter, and then a current value flowing in the sense regions SR can be measured using the ammeter when the above-described operations of the semiconductor device is performed.

Next, examples of materials of the constituent elements will be described.

The p⁺ type semiconductor region 1, the n⁺ type semiconductor region 2, the n⁻ type semiconductor region 3, the p type semiconductor regions 4 and 7, the n⁺ type semiconductor regions 5 and 8, the p⁺ type semiconductor regions 6 and 9, and the p⁺ type semiconductor region 10 contain silicon, silicon carbide, gallium nitride, or gallium arsenide as the semiconductor material. When single crystal silicon is used as the semiconductor material, arsenic, phosphorus, or antimony can be used as n type impurities added to the semiconductor material. Boron can be used as p type impurities.

The gate electrode 20 contains a conductive material such as polysilicon including a doped polysilicon.

The gate insulation layer 21, the insulation portion 25 and the insulation layers 61 and 62 contain an insulating material such as silicon oxide or silicon nitride.

The collector electrode 31, the emitter pad 32, the gate wiring 33, the sense pad 34, and the metal layer 41 are metal layers that contain a metal material such as aluminum.

The plugs 51 to 54 contain a metal material such as titanium or tungsten.

Here, operations and advantages of the present embodiment will be described.

First, a semiconductor device according to a reference example will be described. In the semiconductor device according to the reference example, the sense region SR is formed outside of the region of the plurality of gate electrodes 20. That is, in the semiconductor device according to the reference example, the sense region SR is formed outside the main region MR and spaced from the main region MR. In contrast, in the semiconductor device 100 illustrated in FIGS. 1 to 5, the sense region SR is surrounded by the main region MR.

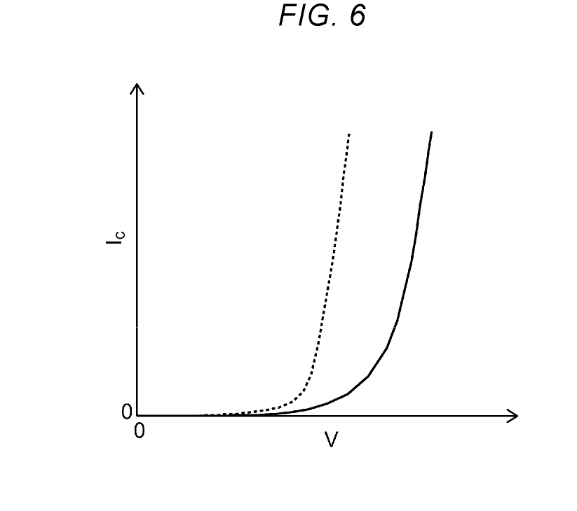

A current-voltage property of the semiconductor device according to the reference example is illustrated in FIG. 6.

FIG. 6 is a graph illustrating a current-voltage property of the semiconductor device according to the reference example.

In FIG. 6, the horizontal axis represents a voltage V of the collector electrode 31 and the vertical axis represents a current density Ic. In FIG. 6, a solid line indicates a current-voltage property in the main region MR and a dotted line indicates a current-voltage property in the sense region SR.

As illustrated in FIG. 6, in the semiconductor device according to the reference example, the current-voltage property in the main region MR is different from the current-voltage property in the sense region SR. The increase in the current density Ic with respect to increasing voltage V is greater in the sense region SR than in the main region MR.

This is because when the sense region SR is formed outside the main region MR, electrons injected into the sense region SR flow toward the collector electrode 31 in the X and Y directions and holes injected from the collector electrode 31 flow to concentrate toward the emitter potential regions of the sense region SR.

When there is a difference between the current-voltage property in the main region MR and the current-voltage property in the sense region SR, abnormity or the like occurring in the main region MR may not be detected based on a current value measured in the sense region SR, for example, despite the fact that the abnormity or the like is occurring in the current value in the main region MR.

In contrast, in the semiconductor device according to the present embodiment, the n⁺ type semiconductor region 8 and the p⁺ type semiconductor region 9 of the sense region SR are formed so as to be adjacent to the n⁺ type semiconductor region 5 and the p⁺ type semiconductor region 6 of the main region MR.

In the semiconductor device that has this structure, when electrons are injected from the n⁺ type semiconductor region 8 into the n⁻ type semiconductor region 3, electrons are similarly also injected from the n⁺ type semiconductor region 5 near the n⁺ type semiconductor region 8 into the n⁻ type semiconductor region 3. Further, holes injected into the n⁻ type semiconductor region 3 flow to the p⁺ type semiconductor region 9 and also flow to the p⁺ type semiconductor region 6 near the p⁺ type semiconductor region 9. Therefore, the concentration of the current in the sense region SR is alleviated, and thus the difference between the current-voltage property in the sense region SR and the current-voltage property in the main region MR can be reduced.

In the semiconductor device according to the present embodiment, the insulation portions 25 are formed between the n⁺ type semiconductor regions 5 and 8 and between the p⁺ type semiconductor regions 6 and 9. Therefore, a current flowing in the sense region SR and a current flowing in the main region MR can be separately measured.

By reducing the difference in the current-voltage property between the sense region SR and the main region MR, it is possible to detect abnormality of a current value in the main region MR with high precision based on a measurement result of a current value in the sense region SR.

When abnormality of a current value in the main region MR is detected, an operation of protecting the semiconductor device is performed, for example, by turning off the semiconductor device or causing a protection circuit connected to the semiconductor device to function. Therefore, by detecting abnormality of a current value in the main region MR with high precision, it is possible to reduce a possibility of breakdown occurring in the semiconductor device and to improve reliability of the semiconductor device.

In the semiconductor device according to the present embodiment, the metal layer 41 is formed between the insulation layers 61 and 62 and connects the sense region SR to the sense pad 34 with the plug 51, the metal layer 41, and the plug 54. When such a structure is adopted, the area of the main region MR can be larger than when the emitter pad 32, the gate wiring 33, the sense pad 34, and the wiring connecting the sense pad 34 to the sense region SR are formed above, for example, the insulation layer 61.

Therefore, according to the present embodiment, it is possible to form the sense region SR in the main region MR while suppressing a reduction in the area of the main region MR.

In the semiconductor device according to the present embodiment, the plurality of sense regions SR are formed within the main region MR. By forming the plurality of sense regions SR in the main region MR, it is possible to detect abnormality of a local current value in the main region MR with higher precision.

The number or arrangement of the sense regions SR formed in the main region MR is n, where n is a whole number greater than one.

In general, in the semiconductor device, breakdown easily occurs in the vicinity of the outer circumference of the main region MR more than in the center of the main region MR. For this reason, more sense regions SR may be formed in the outer circumference of the main region MR than in the center of the main region MR.

Alternatively, when a location where an occurrence frequency of the breakdown is high is known in advance in the main region MR, more sense regions SR can be formed in the vicinity of the location than in other locations, so that abnormality can be detected in the main region MR with higher precision.

### First Modification Example

In the above-described semiconductor device 100, field plate electrodes (hereinafter referred to as FP electrodes) 70 may be formed instead of some of the plurality of gate electrodes 20.

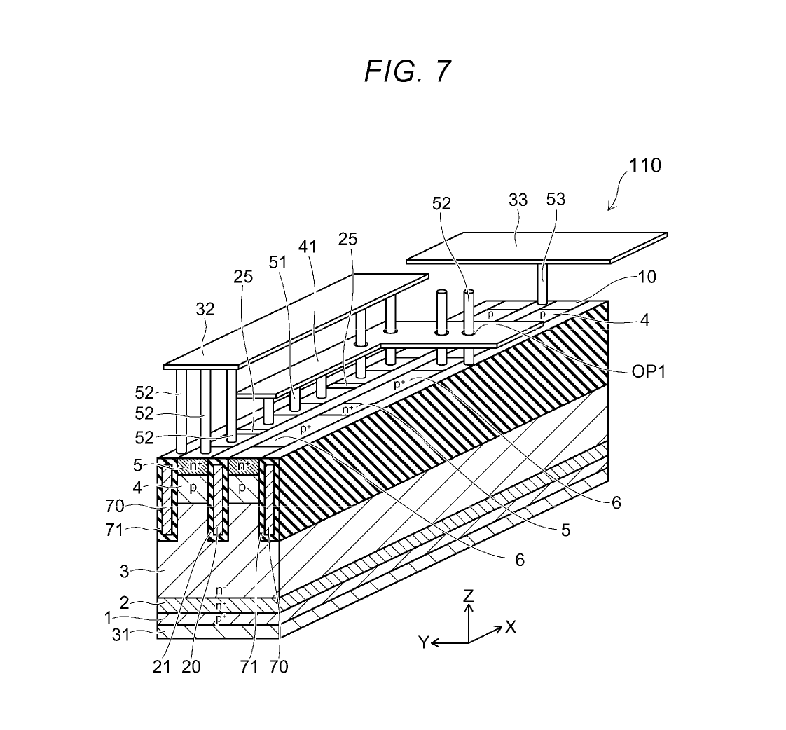

FIG. 7 is a perspective sectional view illustrating a portion of a semiconductor device 110 according to a first modification example of the first embodiment.

In FIG. 7, the insulation layers 61 and 62 are not illustrated, and only a portion of the metal layer 41, a portion of the emitter pad 32, and some of the plurality of plugs 52 are illustrated.

As illustrated in FIG. 7, the FP electrodes 70 are formed inwardly of and extend above the n⁻ type semiconductor region 3 with the insulation layer 71 interposed therebetween and over the portions of the FP electrode 70 extending from the n⁻ type semiconductor region 3. The FP electrode 70 is connected to the emitter pad 32 by the plug 52.

As illustrated in FIG. 7, the plug 52 may connect the FP electrode 70 to the emitter pad 32 through the opening OP1 of the metal layer 41.

In the semiconductor device 110, the sense region SR is formed between the gate electrode 20 and the FP electrode 70. When at least one of the electrodes adjacent to the sense region SR is the gate electrode 20, a channel is formed in the p type semiconductor region 7 so that a current can flow in the sense region SR.

As described above, the semiconductor device according to the first embodiment is an IGBT. The present embodiment can also be applied to a device other than the IGBT. For example, when the present embodiment is applied to an MOSFET, the p⁺ type semiconductor region 1 is omitted from the semiconductor device 100.

### Second Modification Example

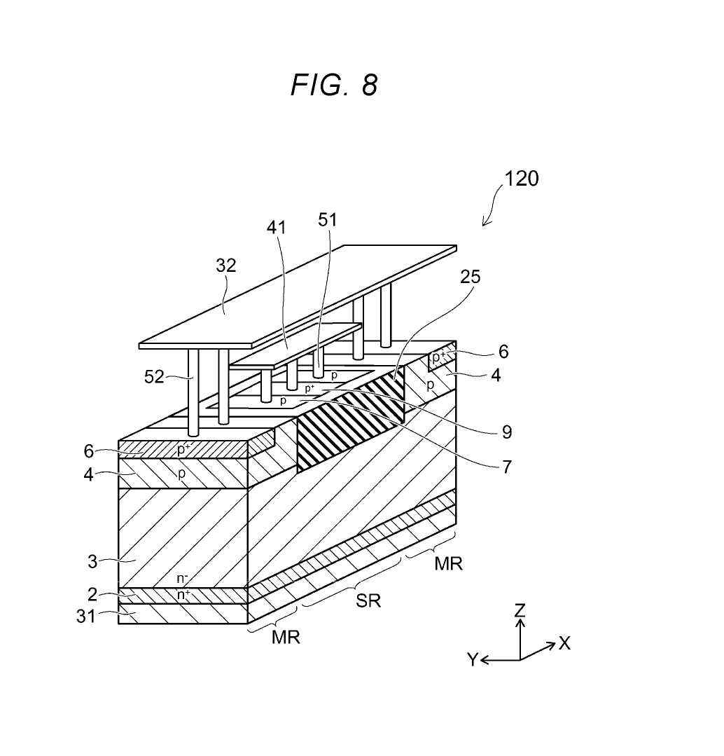

An example of a case in which the first embodiment is applied to a diode will be described with reference to FIG. 8.

FIG. 8 is a perspective sectional view illustrating a portion of a semiconductor device 120 according to a second modification example of the first embodiment.

In the semiconductor device 120, the electrode 31 is used as a cathode electrode and the pad 32 is used as an anode pad.

The semiconductor device 120 includes an n⁺ type semiconductor region 2, an n⁻ type semiconductor region 3, p type semiconductor regions 4, p⁺ type semiconductor regions 6, p type semiconductor regions 7, p⁺ type semiconductor regions 9, insulation portions 25, the cathode electrode 31, the anode pads 32, the metal layers 41, and plugs 51 and 52 and includes sense pads 34, an insulation layer 61, and an insulation layer 62 (none of which is illustrated).

The cathode electrode 31 is formed on the lower surface of the semiconductor device 120.

The n⁺ type semiconductor region 2 is formed above the cathode electrode 31 and is electrically connected to the cathode electrode 31.

The n⁻ type semiconductor region 3 is formed above the n⁺ type semiconductor region 2.

The p type semiconductor regions 4 and 7 are formed above the n⁻ type semiconductor region 3.

The insulation portion 25 is formed near the p type semiconductor region 7. The p type semiconductor regions 4 and 7 are separated by the insulation portion 25.

The p⁺ type semiconductor regions 6 are selectively formed above the p type semiconductor regions 4, and the p⁺ type semiconductor regions 9 are selectively formed above the p type semiconductor regions 7.

The metal layer 41 is formed above the insulation layer 61 (not illustrated), as in the semiconductor device 100.

The p type semiconductor region 7 and p⁺ type semiconductor region 9 are connected to the metal layer 41 by the plug 51.

The metal layer 41 is connected to the sense pad 34 (not illustrated), as in the semiconductor device 100.

That is, the p type semiconductor region 7 and p⁺ type semiconductor region 9 surrounded by the insulation portions 25 are used as the sense region SR.

The anode pad 32 is formed above the metal layer 41 with the insulation layer 62 (not illustrated) interposed therebetween.

The p type semiconductor region 4 and the p⁺ type semiconductor region 6 are connected to the anode pad 32 by the plug 52.

In the present modification example, by flowing a current to the sense region SR surrounded by the main region MR and measuring the current-voltage property, as in the semiconductor device 100, it is possible to detect abnormality of a current value in the main region MR with higher precision. Thus, it is possible to improve reliability of the semiconductor device.

### Third Modification Example

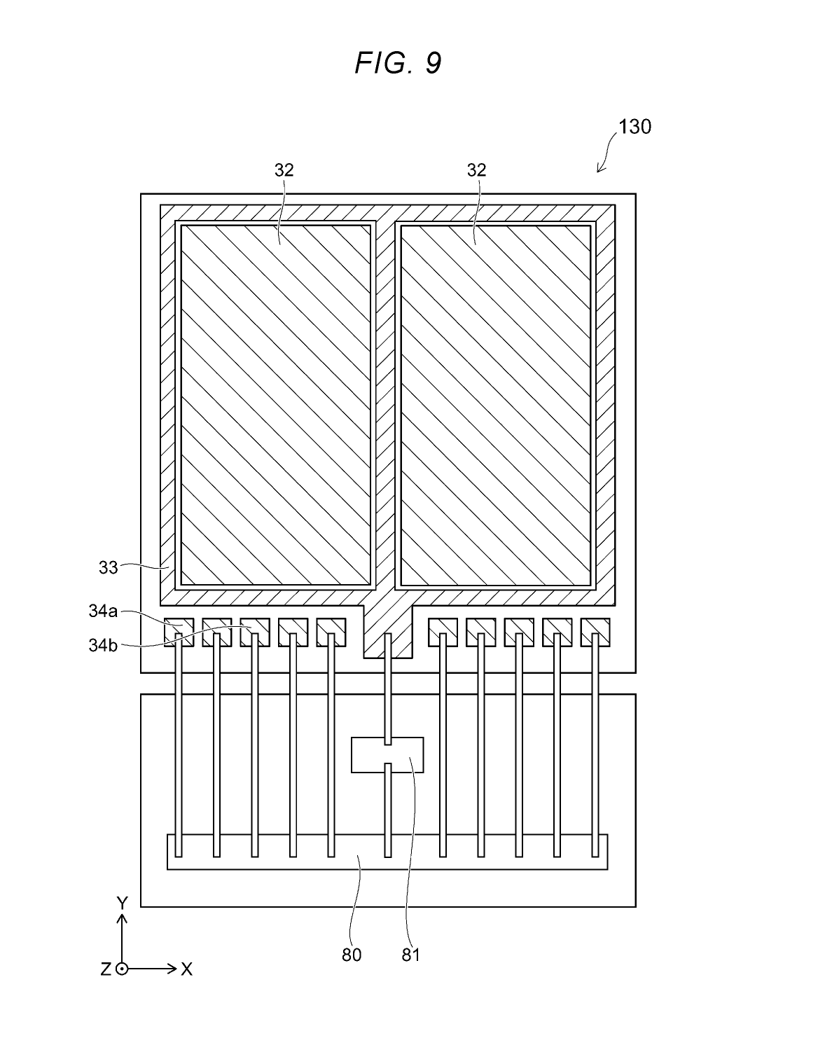

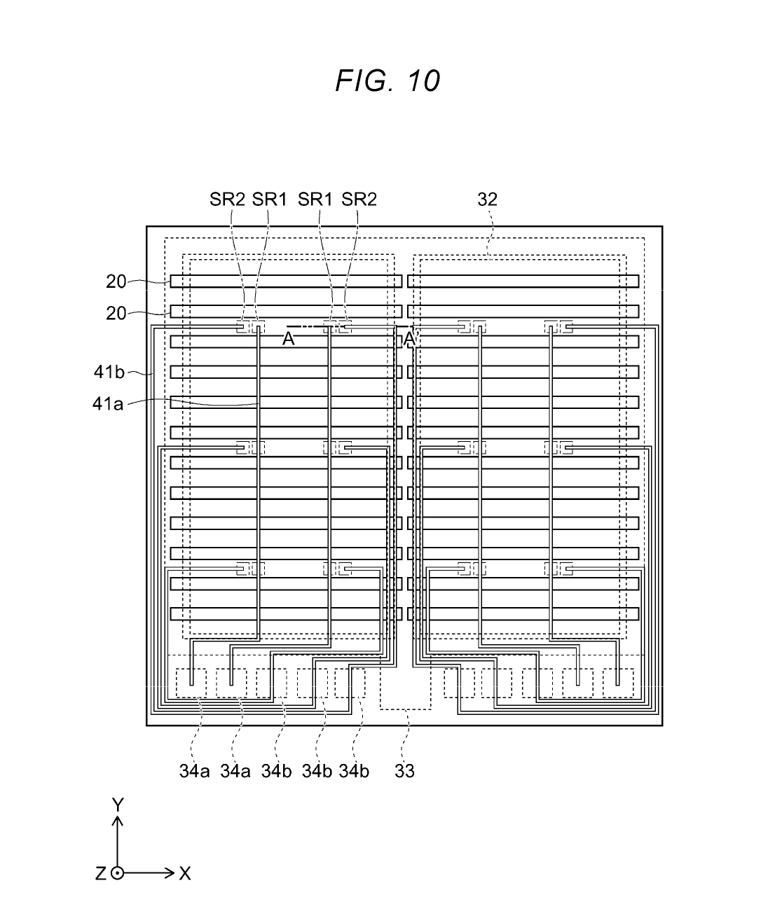

FIGS. 9 and 10 are plan views illustrating a semiconductor device 130 according to a third modification example of the first embodiment.

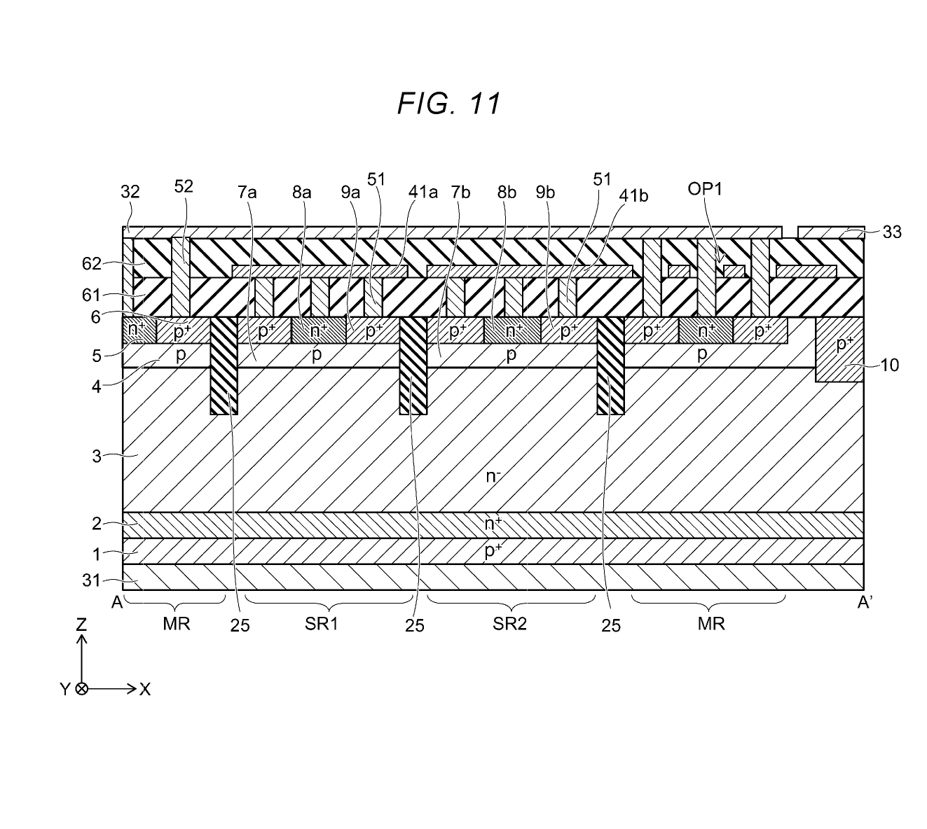

FIG. 11 is a sectional view taken along the line A-A′ in FIG. 10.

In FIG. 10, a current detection unit 80 and a gate driving circuit 81 are not illustrated, and the emitter pads 32, the gate wiring 33, and the sense pads 34 are indicated by dotted lines.

The semiconductor device 130 is different from the semiconductor device 100, for example, in that the current detection unit 80 and the gate driving circuit 81 are further included.

As illustrated in FIG. 9, the current detection unit 80 is connected to the plurality of sense pads 34. The gate driving circuit 81 is connected to the current detection unit 80 and the sense pads 34.

Operations of the current detection unit 80 and the gate driving circuit 81 will be described below.

As illustrated in FIG. 10, metal layers 41a and 41b are formed below the emitter pads 32, the gate wiring 33, and the sense pads 34.

Below the metal layers 41a and 41b, sense regions SR1 and SR2 are partially formed.

The plurality of sense regions SR1 and the plurality of sense regions SR2 are formed in the X and Y directions. Each pair of a sense region SR1 and each sense region SR2 are formed to be close to each other.

Portions of each metal layer 41a are formed above the plurality of sense regions SR1 arranged in the Y direction and are connected to this plurality of sense regions SR1.

Another portion of each metal layer 41a is formed below a sense pad 34a and is connected to the sense pad 34a.

That is, a plurality of columns in which the plurality of sense regions SR1 are arranged spaced apart in the Y direction are spaced apart in the X direction, and each column of sense regions SR1 is connected to each sense pad 34a.

Portions of the metal layers 41b are formed above the plurality of sense regions SR2 arranged in the X direction and each of the metal layers 41b are connected to one of the plurality of sense regions SR2.

Another portion of each of these metal layers 41b is formed below an individual sense pad 34b and is connected to that sense pad 34b.

That is, a plurality of rows in which the plurality of sense regions SR2 are spaced apart in the X direction are formed in the Y direction, and the row of each sense region SR2 is connected to each sense pad 34b. Thus two each of the sense pads SR2 are connected to a single sense pad 34b.

As illustrated in FIG. 11, in the sense region SR1, a p type semiconductor region 7a is formed, and an n⁺ type semiconductor region 8a and a p⁺ type semiconductor region 9a are selectively formed above the p type semiconductor region 7a. The n⁺ type semiconductor region 8a and the p⁺ type semiconductor region 9a are connected to the metal layer 41a by the plug 51.

In the sense region SR2, a p type semiconductor region 7b is formed, and an n⁺ type semiconductor region 8b and a p⁺ type semiconductor region 9b are selectively formed above the p type semiconductor region 7b. The n⁺ type semiconductor region 8b and the p⁺ type semiconductor region 9b are connected to the metal layer 41b by the plug 51.

The insulation portions 25 are formed between the p type semiconductor region 4, the p type semiconductor region 7a, and the p type semiconductor region 7b. The p type semiconductor region 7a and the p type semiconductor region 7b are surrounded by the insulation portions 25 and the gate insulation layer 21 (not illustrated).

Accordingly, currents flowing in the sense regions SR1 and SR2 can be separately detected.

As illustrated in FIG. 11, the opening OP1 may be formed in the metal layer 41b, and semiconductor regions of the metal layer 32 and the main region MR may be connected by the plugs 52 through the opening OP1. Similarly, the openings OP1 may be formed in the metal layer 41a.

Next, an operation of the semiconductor device according to the present modification example will be described.

The current detection unit 80 is a comparator that compares currents flowing in the sense pads 34.

Specifically, the current detection unit 80 first compares current values flowing in two sense pads 34a and extracts the sense pad 34a in which a larger current flows. The current detection unit 80 performs this operation on all of the sense pads 34a to extract the sense pad 34a in which the largest current flows. Next, the current detection unit 80 extracts the sense pad 34b in which the largest current flows in accordance with the same method.

Subsequently, the current detection unit 80 compares the current value (first current value) flowing in the extracted sense pad 34a to a predetermined threshold value (first threshold value). The current detection unit 80 compares the current value (second current value) flowing in the extracted sense pad 34b to a predetermined threshold value (second threshold value). When at least one of the current values exceeds the threshold value, the current detection unit 80 transmits the determination result to the gate driving circuit 81.

For example, when receiving a signal from the current detection unit 80, the gate driving circuit 81 starts applying a voltage to the gate wiring 33.

Here, advantages of the present modification example will be described.

The gate driving circuit 81 turns on the semiconductor device by applying the voltage of the gate electrode 20 via the gate wiring 33.

Thereafter, when the application of the voltage stops from the gate driving circuit 81, the semiconductor device starts to transition from the on-state to the off-state.

At this time, a difference occurs in a time necessary until the voltage drops between the gate electrodes 20. When the voltage of some of the gate electrodes 20 is higher than the voltage of the other gate electrodes 20, the current concentrates in the vicinities of some of the gate electrodes 20.

When a large current flows locally in the semiconductor device in a continuous state, the semiconductor device is broken down in some cases.

When large currents flow locally in the semiconductor device, larger currents than those of other sense regions flow in the sense regions SR1 and SR2 close to the position where the currents flow. At this time, when at least one of first and second current values exceeds a threshold value, as described above, a signal is transmitted to the gate driving circuit 81 and the gate driving circuit 81 applies a voltage to the gate wiring 33.

That is, the gate driving circuit 81 applies a voltage to the gate electrodes 20 again while the gate electrodes 20 transition from the on-state to the off-state. Accordingly, channels are formed again near the gate electrodes 20 and the current flowing locally in the semiconductor device distributes and flows to the channels.

According to the present modification example, the state in which the large current flows locally in the semiconductor device can be detected and a maximum current value can be reduced. Therefore, it is possible to reduce the possibility of the breakdown of the semiconductor device occurring.

According to the present modification example, it is possible to specify an approximate spot in which a large current flows. This is performed in accordance with, for example, the following method.

First, as described above, the current detection unit 80 extracts the sense pads 34a and 34b in which a largest current flows. Accordingly, it is possible to specify the column of the sense region SR1 in which the largest current flows and to specify the row of the sense region SR2 in which the largest current flows. By specifying the column of the sense region SR1 and the row of the sense region SR2 in which the large currents flow, it is possible to specify a pair of sense regions SR1 and SR2 in which the larger currents than those of the other sense regions flow.

Alternatively, the column of the sense region SR1 in which the largest current flows is compared to the row of the sense region SR2 in which the largest current flows. When a current value of one of the currents is greater than a current value of the other, it can be known that the large current flows in a plurality of spots arranged in the row direction or the column direction.

The current detection unit 80 may be a current monitor. That is, the current detection unit 80 may measure currents flowing in the column of the sense regions SR1 and the row of the sense regions SR2. In this case, the semiconductor device 130 may not include the gate driving circuit 81, and the gate wiring 33 may be connected to an external gate driving circuit.

First, the current detection unit 80 compares the current flowing in each of the sense pads 34a and 34b to a predetermined threshold value. When one of the currents exceeds the threshold value, a signal is transmitted to an external circuit connected to the current detection unit 80.

For example, by measuring a leakage current flowing in the semiconductor device using the current detection unit 80, it is possible to detect an increase in the leakage current due to temporal deterioration in the semiconductor device and to confirm a lifetime of the semiconductor device.

In the example illustrated in FIGS. 9 and 10, the IGBT and the control unit of the current detection unit 80 and the gate driving circuit 81 are formed in separate chips, but may be formed in one chip. Alternatively, the chip in which the IGBT is formed and the chip in which the control unit of the current detection unit 80 and the gate driving circuit 81 are formed may be stacked by a chip-on-chip technology.

### Fourth Modification Example

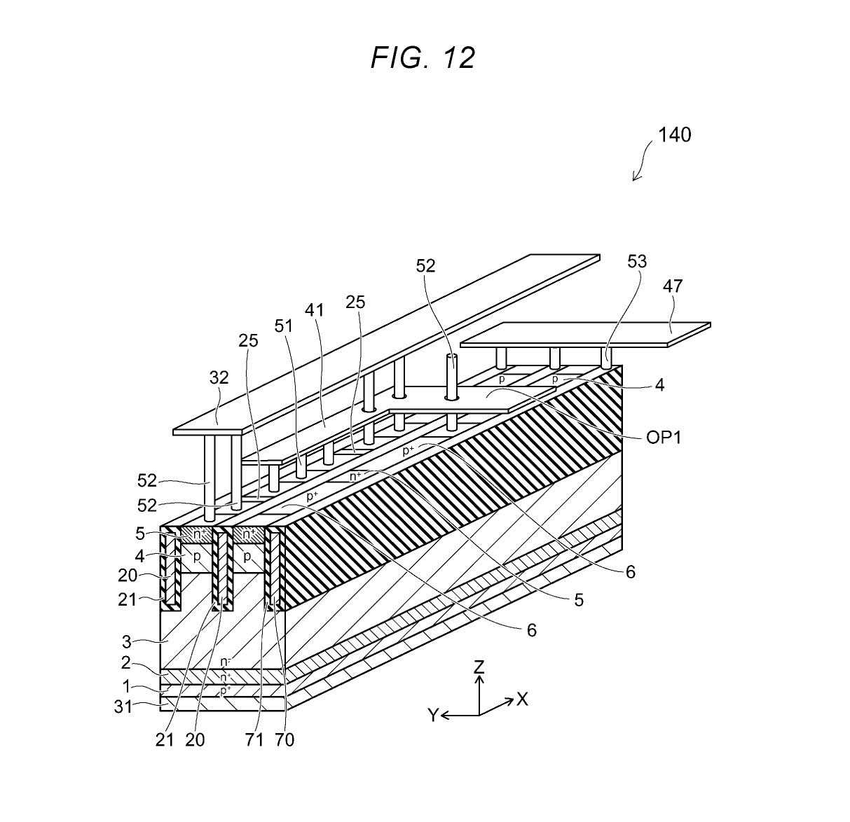

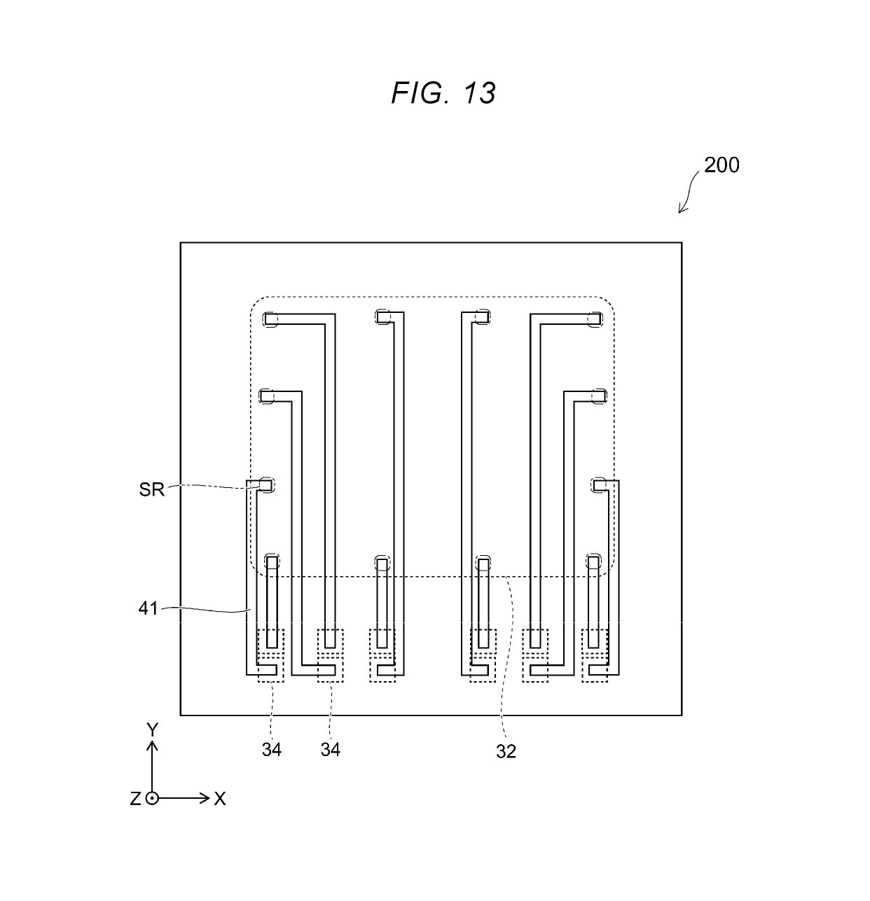

FIG. 12 is a perspective sectional view illustrating a portion of a semiconductor device 140 according to a fourth modification example of the first embodiment.

In the semiconductor device 140, as illustrated in FIG. 12, a metal layer 47 extending in the Y direction is formed below the emitter pad 32. The metal layer 47 is connected to the gate electrodes 20 by the plugs 53. The metal layer 47 is connected to the gate wiring 33 by a plug (not illustrated).

In the semiconductor device 100, as illustrated in FIGS. 1 to 3, a portion of the gate wiring 33 is formed between the emitter pads 32. The portion of the gate wiring 33 is connected to the gate electrodes 20.

In the semiconductor device 140 according to the present modification example, meanwhile, the gate wiring 33 is not formed between the emitter pads 32 and the emitter pads 32 may be formed integrally on the upper surface of the semiconductor device 140.

Even in this case, by forming the metal layer 47 below the emitter pad 32, it is possible to connect the gate electrodes 20 to the gate wiring 33 with the metal layer 47.

### Second Embodiment

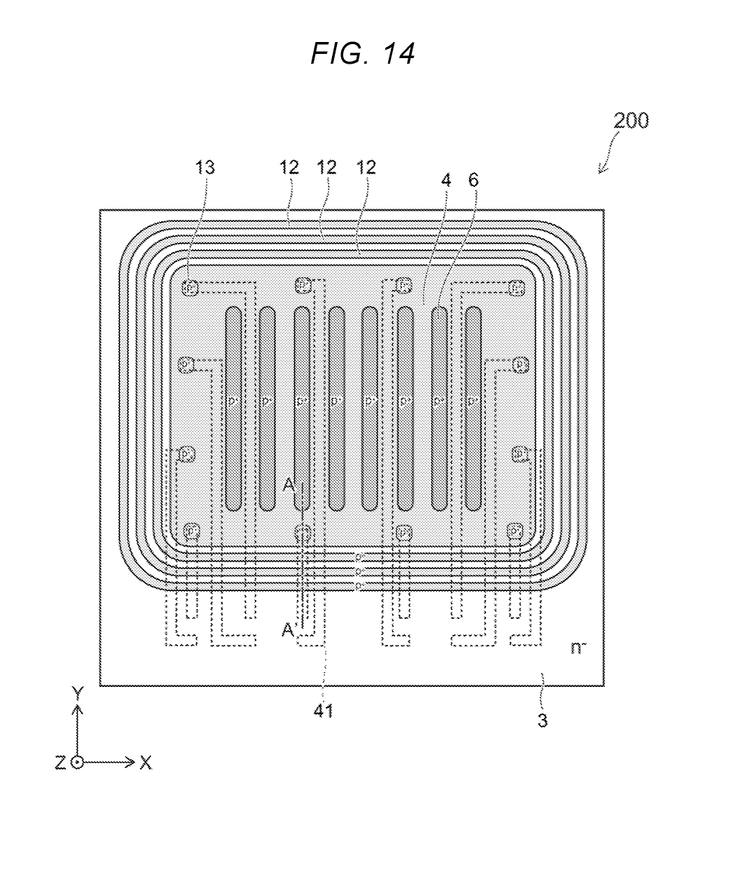

FIGS. 13 and 14 are plan views illustrating a semiconductor device 200 according to a second embodiment.

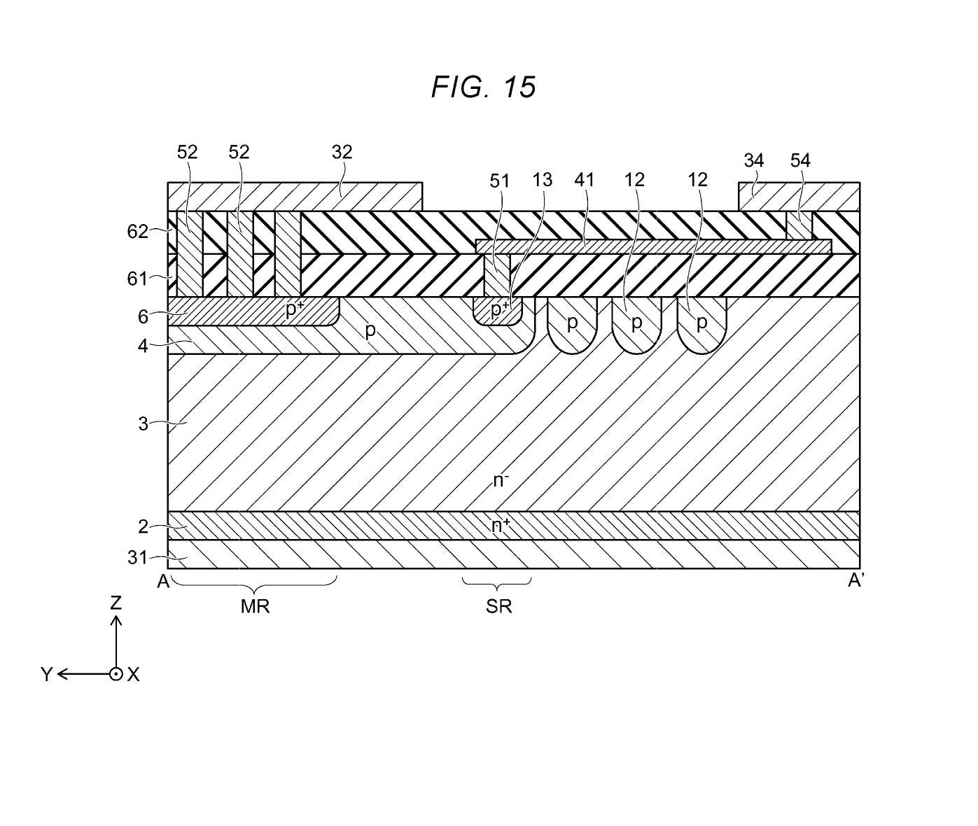

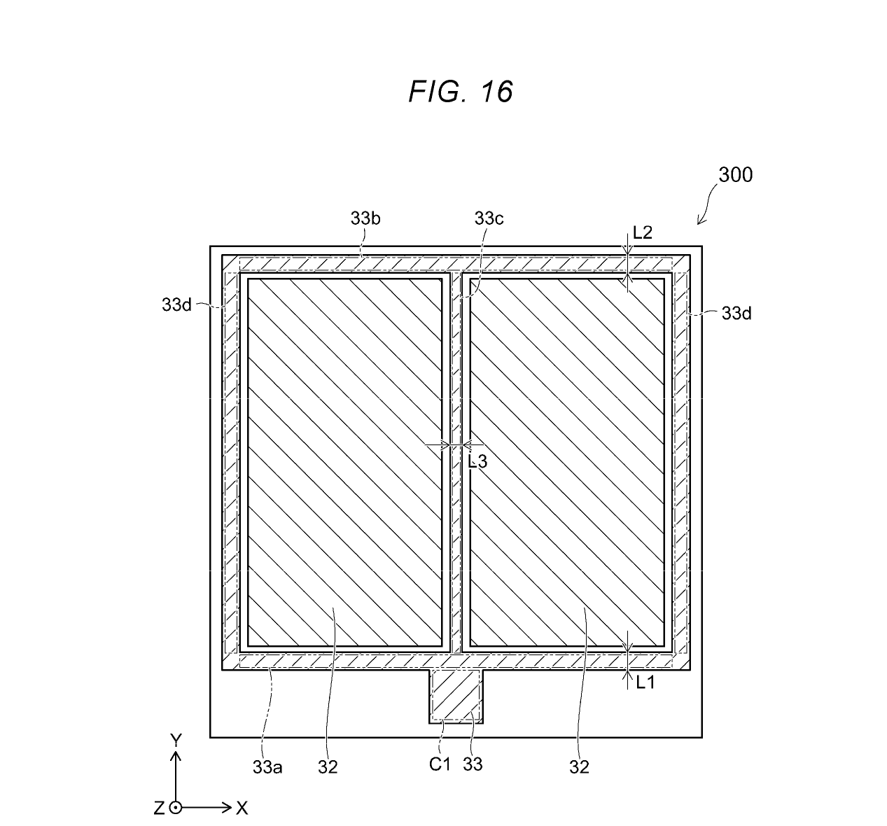

FIG. 15 is a sectional view taken along the line A-A′ in FIG. 14.

In FIG. 13, sense pads 34 and anode pads 32 are indicated by dotted lines and the constituent elements other than a metal layer 41 are not illustrated.

In FIG. 14, the sense pads 34 are indicated by dotted lines and the anode pad 32, plugs 51, 52, and 54, and insulation layers 61 and 62 are not illustrated.

The semiconductor device 200 is a diode.

As illustrated in FIGS. 13 to 15, the semiconductor device 200 includes an n⁺ type semiconductor region 2, an n type semiconductor region 3, p type semiconductor regions 4, p⁺ type semiconductor regions 6, p type guard ring regions 12, p⁺ type semiconductor regions 13, a cathode electrode 31, the anode pads 32, sense pads 34, metal layers 41, plugs 51, plugs 52, plugs 54, an insulation layer 61, and an insulation layer 62.

As illustrated in FIG. 13, the anode pads 32 and the sense pads 34 are formed on the upper surface of the semiconductor device 200.

The plurality of metal layers 41 are formed below the anode pads 32 and the sense pads 34, as in the semiconductor device 100. A portion of each of the metal layers 41 is formed below the sense pads 34 and a portion of each metal layer is formed above the sense regions SR.

As illustrated in FIG. 14, the p⁺ type semiconductor region 13 is formed in the sense region SR.

As illustrated in FIG. 15, the cathode electrode 31 is formed on the lower surface of the semiconductor device 120.

The n⁺ type semiconductor region 2 is formed above the cathode electrode 31 and is electrically connected to the cathode electrode 31.

The n⁻ type semiconductor region 3 is formed above the n⁺ type semiconductor region 2.

The p type semiconductor region 4 is selectively formed above the n⁻ type semiconductor region 3.

The p⁺ type semiconductor region 6 is selectively formed above the p type semiconductor region 4.

The p⁺ type semiconductor region 13 is formed above the p type semiconductor region 4 and spaced from the p⁺ type semiconductor region 6.

As illustrated in FIG. 14, the plurality of p⁺ type semiconductor regions 6 are spaced apart in the X direction and each extends in the Y direction. The plurality of p⁺ type semiconductor regions 13 are arranged in a circumferentially around the plurality of p⁺ type semiconductor regions 6.

The p⁺ type semiconductor regions 6 are not limited to the example illustrated in FIG. 14, but the plurality of p⁺ type semiconductor regions may be formed along a grid in the X and Y directions. Alternatively, one p⁺ type semiconductor region 6 with a larger area may be formed above the p type semiconductor regions 4.

As illustrated in FIG. 15, the insulation layer 61 is formed above the p type semiconductor regions 4, the p⁺ type semiconductor regions 6, the p type guard ring regions 12, and the p⁺ type semiconductor regions 13.

The metal layers 41 are formed above the insulation layers 61.

The insulation layers 62 are formed above the metal layers 41.

The sense pad 34 and the anode pad 32 are formed above the insulation layers 62.

The p⁺ type semiconductor region 13 is connected to the metal layer 41 by the plug 51, and the metal layer 41 is connected to the sense pad 34 by the plug 52.

The p⁺ type semiconductor region 6 is connected to the anode pad 32 by the plug 52.

In the semiconductor device according to the present embodiment, the p⁺ type semiconductor region 13 which is the sense region SR is formed in the vicinity of the p⁺ type semiconductor region 6 and spaced from the p⁺ type semiconductor region 6 which is in the main region MR. In the vicinity of the p⁺ type semiconductor region 6, electric field concentration easily occurs and an avalanche breakdown easily occurs more than in the region in which the p⁺ type semiconductor region 6 is formed. For this reason, carriers are generated locally due to the avalanche breakdown, and thus current flows in some cases. By measuring a current flowing in the vicinity of the p⁺ type semiconductor region 6 through the p⁺ type semiconductor region 13, abnormality of a current value can be detected even when the abnormality of the current value occurs.

The plurality of the sense regions SR are preferably formed in the vicinity of the p⁺ type semiconductor region 6. By forming the plurality of sense regions SR, it is possible to detect the local abnormality of the current value in the vicinity of the p⁺ type semiconductor region 6 with higher precision.

According to the present embodiment, the sense pads 34 and the p⁺ type semiconductor regions 13 are connected via the metal layers 41 formed above the insulation layers 61. By adopting such a configuration, it is possible to arrange the plurality of sense pads 34 in one location and easily connect the sense pads 34 to the p⁺ type semiconductor regions 13 interspersed in the p-type semiconductor region 4 and adjacent to the outer circumference of the semiconductor device.

It is not necessary to decrease the area of the anode pad 32 by a wiring connecting each sense pad 34 to each p⁺ type semiconductor region 13 and decrease the area of the main region MR.

Therefore, according to the present embodiment, it is possible to form the plurality of the p⁺ type semiconductor regions 13 connected to the sense pads 34 adjacent to the outer circumference of the semiconductor device while suppressing a reduction in the areas of the main regions MR.

In the semiconductor device according to the present embodiment, the p⁺ type semiconductor region 13 which is the sense region SR is formed in the vicinity of the p⁺ type semiconductor region 6 and spaced from the p⁺ type semiconductor region 6 which is in the main region MR. In the vicinity of the p⁺ type semiconductor region 6, a depletion layer is not extended more than the main region MR in which the p⁺ type semiconductor region 6 is formed and avalanche breakdown easily occurs due to electric field concentration or the like. For this reason, carriers are locally generated due to the avalanche breakdown, and thus current flows in some cases. By measuring a current flowing in a termination region through the p⁺ type semiconductor region 13, abnormality of a current value can be detected even when the abnormality of the current value occurs in a termination region.

The plurality of the sense regions SR are preferably formed in the vicinity of or in the p type semiconductor region 4. By forming the plurality of sense regions SR, it is possible to detect the local abnormality of the current value in the termination region with higher precision.

According to the present embodiment, the sense pads 34 and the p⁺ type semiconductor regions 13 are connected via the metal layers 41 formed above the insulation layer 61. By adopting such a configuration, it is possible to arrange the plurality of sense pads 34 in one location and easily connect the sense pads 34 to the p⁺ type semiconductor regions 13 interspersed in p type semiconductor region 4 adjacent to the outer circumference of the semiconductor device. It is not necessary to decrease the area of the anode pad 32 by a wiring connecting each sense pad 34 to each p⁺ type semiconductor region 13 and decrease the area of the main region MR.

Therefore, according to the present embodiment, it is possible to form the plurality of the p⁺ type semiconductor regions 13 connected to the sense pads 34 in the outer circumference of the semiconductor device while suppressing a reduction in the areas of the main regions MR.

Even in the present embodiment, as in the first embodiment, the metal layer 41 may have the opening OP1, and the plug 52 may connect the p⁺ type semiconductor region 6 to the anode pad 32 through the opening OP1.

### Third Embodiment

FIGS. 16 to 18 are plan views illustrating a semiconductor device 300 according to a third embodiment.

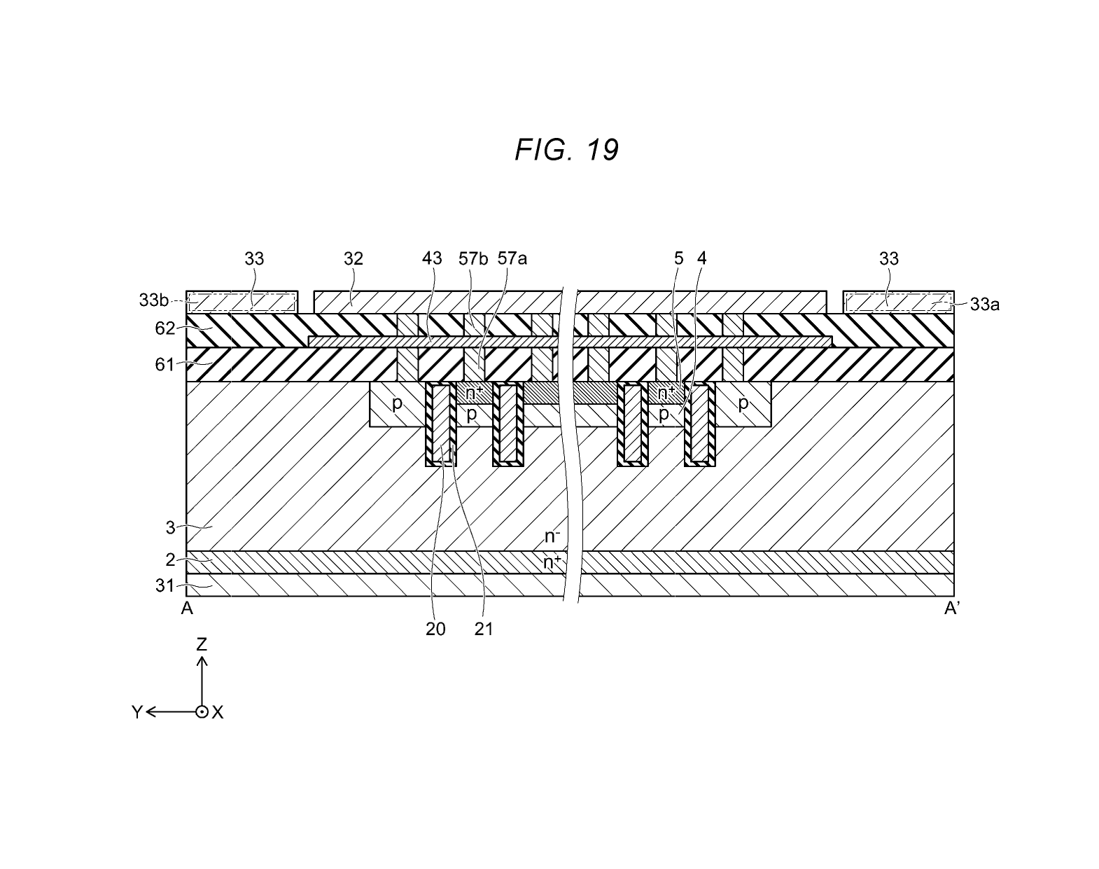

FIG. 19 is a sectional view taken along the line A-A′ in FIG. 18.

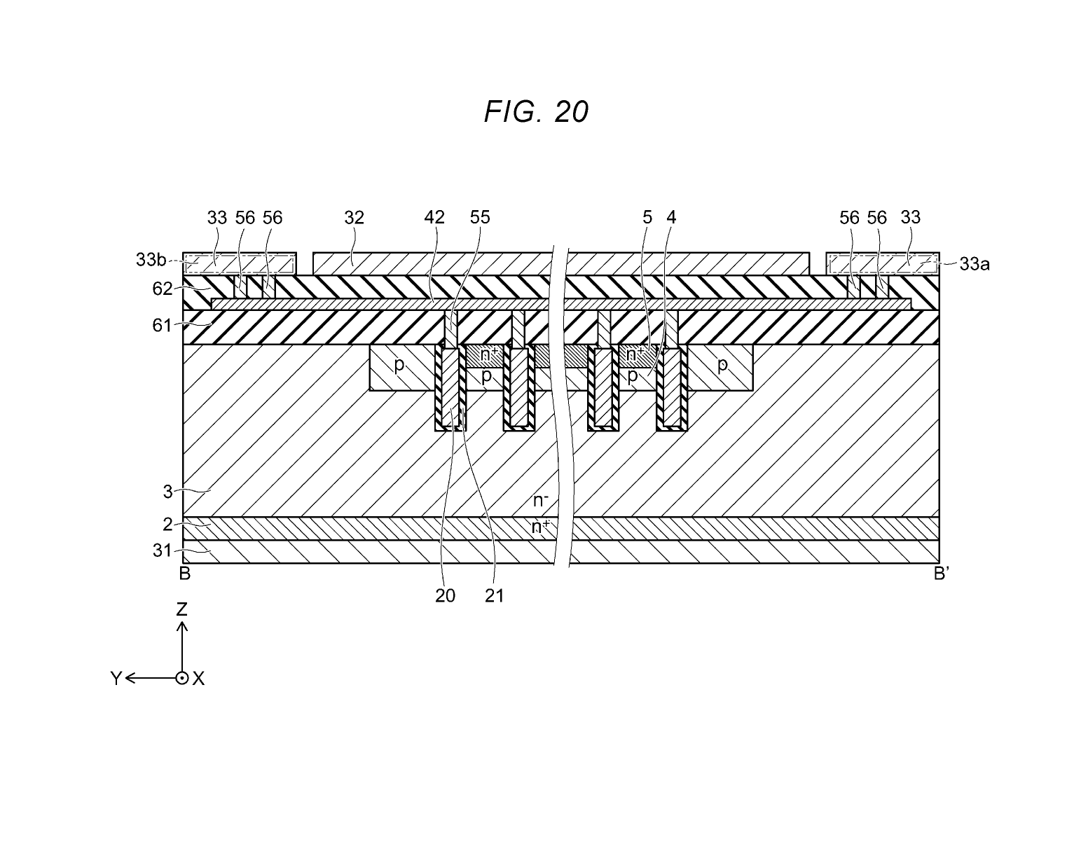

FIG. 20 is a sectional view taken along the line B-B′ in FIG. 18.

In FIG. 16, source pads 32 and a gate wiring 33 are indicated by dotted lines.

In FIG. 18, the source pads 32, the gate wiring 33, insulation layers 61 and 62 are not illustrated and metal layers 42 and 43 are indicated by dotted lines.

The semiconductor device 300 is a MOSFET.

In the semiconductor device 300, the electrode 31 is used as a drain electrode and the pad 32 is used as a source pad.

As illustrated in FIGS. 16 to 20, the semiconductor device 300 includes the n⁺ type semiconductor region 2, the n type semiconductor region 3, the p type semiconductor regions 4, the n⁺ type semiconductor regions 5, the gate electrodes 20, the gate insulation layers 21, the drain electrode 31, the source pads 32, the gate wiring 33, the metal layer 42, the metal layer 43, plugs 55 to 57, an insulation layer 61, and an insulation layer 62.

As illustrated in FIG. 16, the source pads 32 and the gate wiring 33 are formed on the upper surface of the semiconductor device 300 spaced apart from each other.

The gate wiring 33 includes a first extension portion 33a, a second extension portion 33b, a third extension portion 33c, fourth extension portions 33d, and a pad portion C1.

The first extension portion 33a and the second extension portion 33b are spaced apart from each other in the Y direction and each extends in the X direction. The first extension portion 33a is formed closer to the pad portion C1 than the second extension portion 33b. That is, at least a portion of the first extension portion 33a is formed between the second extension portion 33b and the pad portion C1.

The third extension portion 33c and the fourth extension portions 33d are spaced apart from each other in the X direction and each extends in the Y direction. The third extension portion 33c and the fourth extension portions 33d are formed between the first extension portion 33a and the second extension portion 33b and they extend in the Y direction.

The third extension portion 33c is formed between the source pads 32 in the X direction. The source pads 32 are formed between the third extension portion 33c and the two fourth extension portions 33d in the X direction. The third extension portion 33c bisects the source pad 32 into to sub-pads 32.

For example, a width L1 of the first extension portion 33a in the Y direction is larger than a width L3 of the third extension portion 33c in the X direction. Similarly, a width L2 of the second extension portion 33b in the Y direction is larger than the width L3.

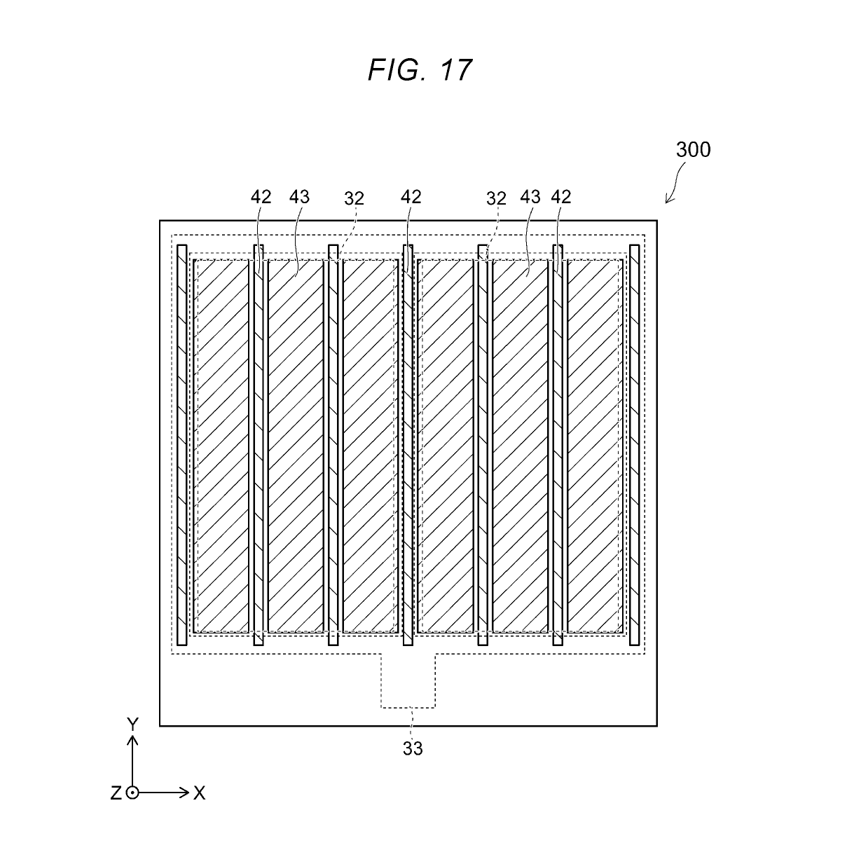

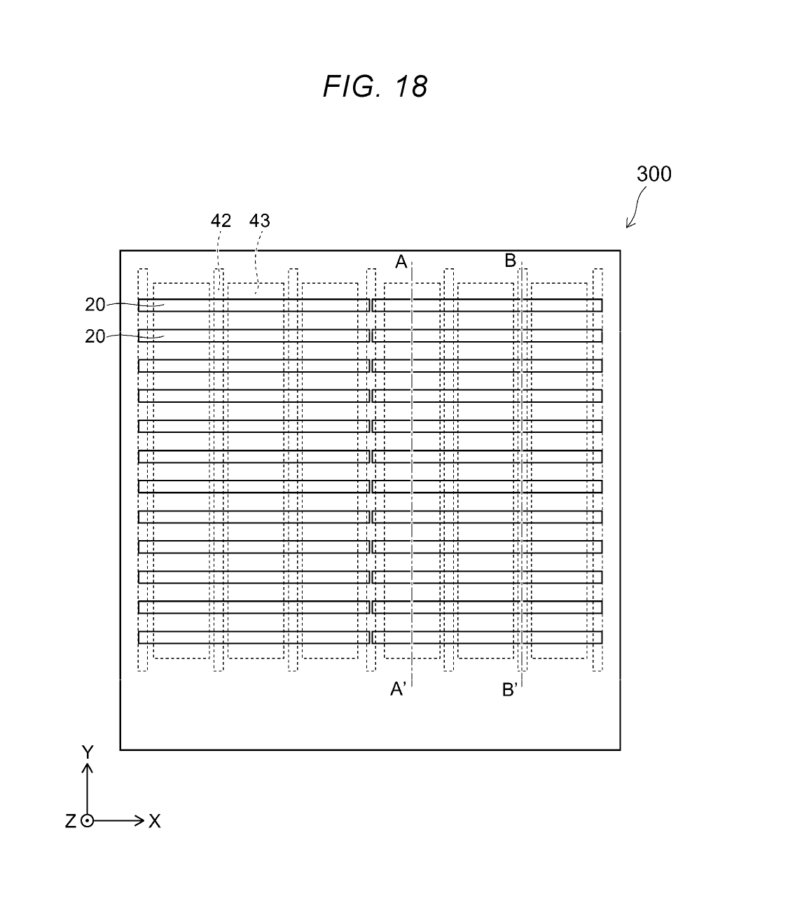

As illustrated in FIG. 17, the metal layers 42 and 43 are formed below the source pads 32 and the gate wiring 33 and spaced apart from each other. The plurality of metal layers 42 and the plurality of metal layers 43 are formed spaced apart in the X direction and each extends in the Y direction.

While the metal layers 42 are formed below the source pads 32 and the gate wiring 33, the metal layers 43 are formed only below the source pads 32.

As illustrated in FIG. 18, the gate electrodes 20 are formed below, and cross underneath, the metal layers 42 and 43. The plurality of gate electrodes 20 are spaced apart in the Y direction below the source pads 32 and each extend in the X direction.

As illustrated in FIG. 19, the drain electrode 31 is formed on the lower surface of the semiconductor device 300.

The n⁺ type semiconductor region 2 is formed above the drain electrode 31 and electrically connects to the drain electrode 31.

The n⁻ type semiconductor region 3 is formed above the n⁺ type semiconductor region 2.

The gate electrode 20 is formed extending into and above the n⁻ type semiconductor region 3 with the gate insulation layer 21 interposed between the n⁻ type semiconductor region 3 and the gate electrode 20, and also over the portion of the gate electrode 20 extending from the n⁻ type semiconductor region 3.

The p type semiconductor region 4 is formed between the gate electrodes 20 above the n⁻ type semiconductor region 3, and the n⁺ type semiconductor region 5 is selectively formed above the p type semiconductor region 4. The gate insulation layer 21 extends between the n+ type semiconductor region 5 and the gate electrode 20 and between the p type semiconductor region 4 and the gate electrode 20, and also covers the upper surface of the gate electrode 20.

The insulation layer 61 is formed above the n⁺ type semiconductor regions 5 and the portion of the gate insulation layer 21 covering the gate electrodes 20.

The metal layers 42 and 43 are formed above the insulation layer 61.

The insulation layer 62 is formed above the metal layers 42 and 43.

The source pads 32 and the gate wiring 33 are formed above the insulation layer 62.

As illustrated in FIG. 19, a plug 57a is formed in the insulation layer 61 and connects the metal layer 43 to the n⁺ type semiconductor region 5.

A plug 57b is formed in the insulation layer 62 and connects the source pad 32 to the metal layer 43.

That is, the n⁺ type semiconductor region 5 is connected to the source pad 32 via the plug 57a, the metal layer 43, and the plug 57b.

As illustrated in FIG. 20, the plug 55 is formed in the insulation layer 61 and connects the metal layer 42 to the gate electrode 20.

The plug 56 is formed in the insulation layer 62 and connects the metal layer 42 to the gate wiring 33.

That is, the gate electrode 20 is connected to the gate wiring 33 by the plug 55, the metal layer 42, and the plug 56.

In the example illustrated in FIG. 19, the plugs 57a and 57b are connected by the metal layer 43, but the source pad 32 and the n⁺ type semiconductor region 5 may be directly connected by one plug without using the metal layer 43.

When a voltage is applied to the gate wiring 33 by a wiring connected to the pad portion C1 and the voltages of the gate electrodes 20 increase and the voltages of the gate electrodes 20 reach a threshold value or higher, the semiconductor device is turned on. At this time, between the gate electrodes 20 formed at positions close to the pad portion C1 and the gate electrodes 20 formed at positions distant from the pad portion C1, a difference in a time (gate delay time) occurs until the voltages of the gate electrodes 20 reach the threshold value or higher. Specifically, when the voltage is applied to the gate wiring 33, the time until the voltage reaches the threshold value or higher is longer the more distant the gate electrode 20 is from the pad portion C1. When the difference in the gate delay time between the gate electrodes 20 is large, currents temporarily concentrate in the vicinity of the gate electrode 20 close to the pad portion C1 after application of the voltage on the gate wiring 33, and thus the semiconductor device may be broken down in some cases.

In particular, when the semiconductor device is manufactured using an LSI process or the like, the thicknesses of the extension portions 33a to 33d of the gate wiring 33 in the Z direction are thin, electric resistance increases in the gate wiring 33, and thus a difference in the gate delay time is larger.

In the semiconductor device according to the present embodiment, the first extension portion 33a and the second extension portion 33b are connected by the metal layer 42 via the plugs 56. The metal layer 42 and each gate electrode 20 are connected by the plug 55.

In such a structure, current paths between the pad portion C1 and the gate electrodes 20 can be increased compared to when the third extension portion 33c and the fourth extension portions 33d are directly connected to the gate electrodes 20 and a voltage is applied to the gate electrodes 20 by only the third extension portion 33c and the fourth extension portions 33d.

Therefore, by connecting the first extension portion 33a close to the pad portion C1 to the second extension portion 33b distant from the pad portion C1 by the metal layer 42, it is possible to decrease the difference in the gate delay time between the gate electrodes 20 formed near the first extension portion 33a and the gate electrodes 20 formed near the second extension portion 33b.

That is, according to the present embodiment, it is possible to decrease the difference in the gate delay time when a voltage is applied to the gate electrodes and to reduce the possibility of breakdown of the semiconductor device occurring. Thus, it is possible to improve reliability of the semiconductor device.

In particular, such a structure is more effective when the width L3 is smaller than the widths L1 and L2. In order to increase the area (effective area) of a region in which a current flows in the semiconductor device, the width L3 of the third extension portion 33c passing through the center of the semiconductor device is preferably smaller. However, when the width L3 is decreased, electric resistance increases in the third extension portion 33c, and thus the difference in the gate delay time may increase.

In the present embodiment, the metal layer 42 is connected to the first extension portion 33a and the second extension portion 33b. That is, even when the width L3 is smaller than the widths L1 and L2, the metal layer 42 is connected to the first extension portion 33a and the second extension portion 33b with lower electric resistance. Therefore, according to the present embodiment, it is possible to increase the effective area while suppressing the increase in the difference in the gate delay time.

### First Modification Example

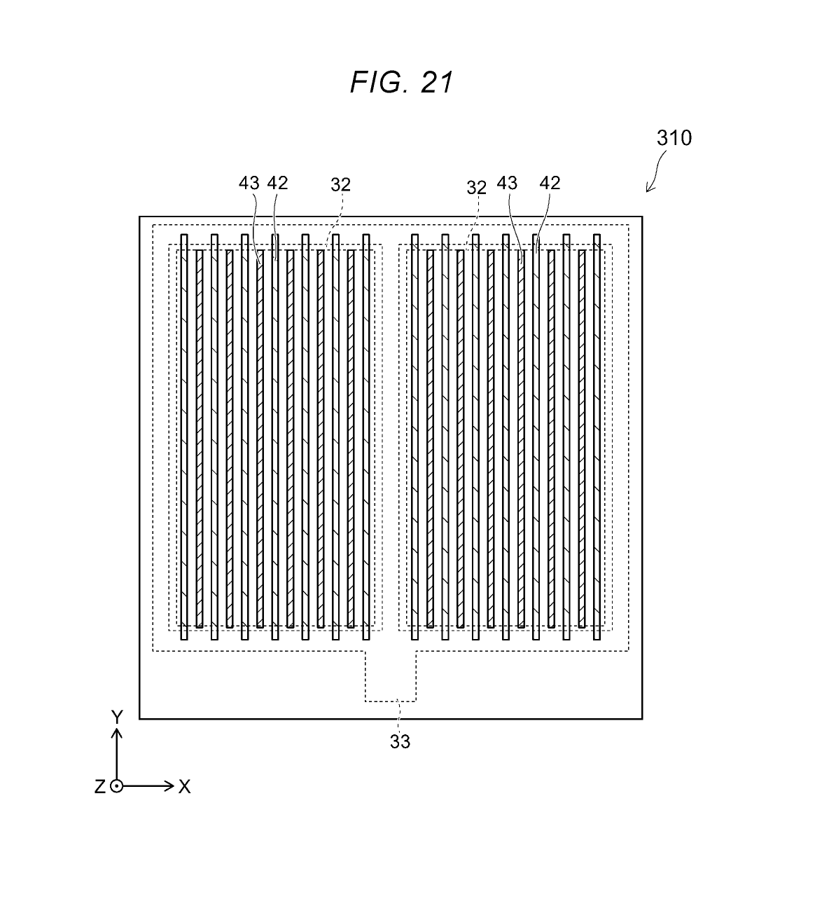

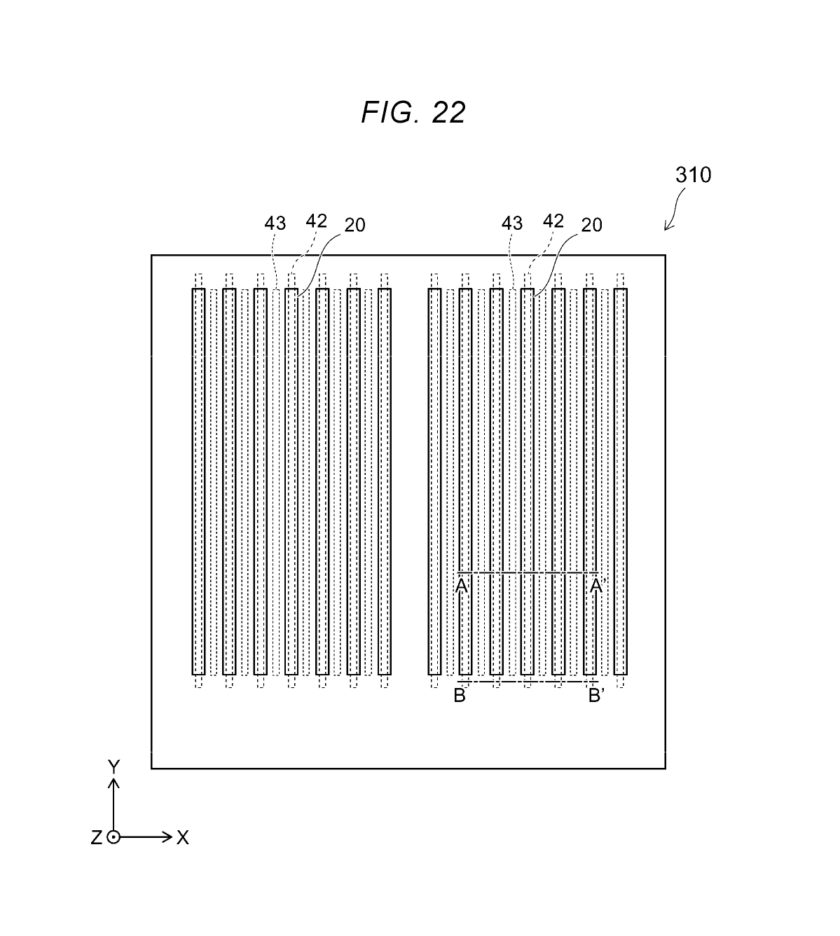

FIGS. 21 and 22 are plan views illustrating a semiconductor device 310 according to a first modification example of the third embodiment.

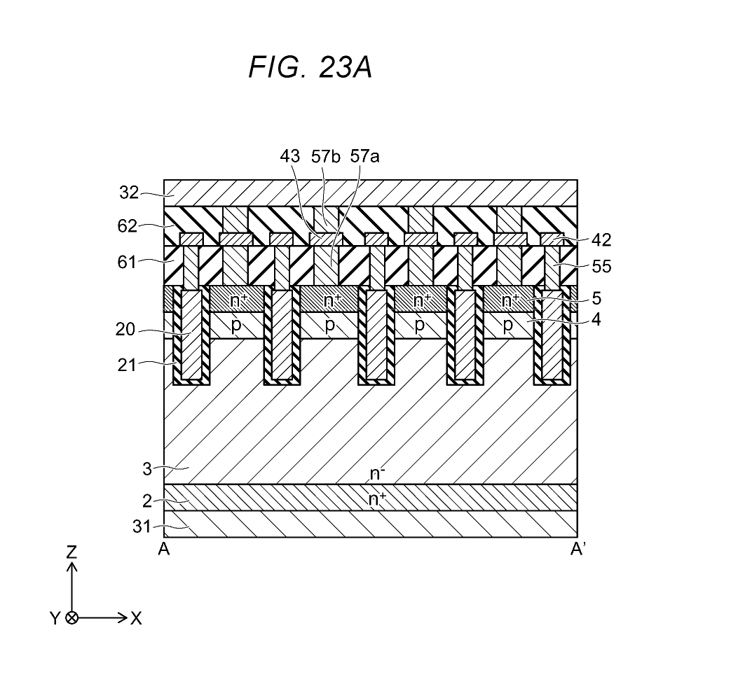

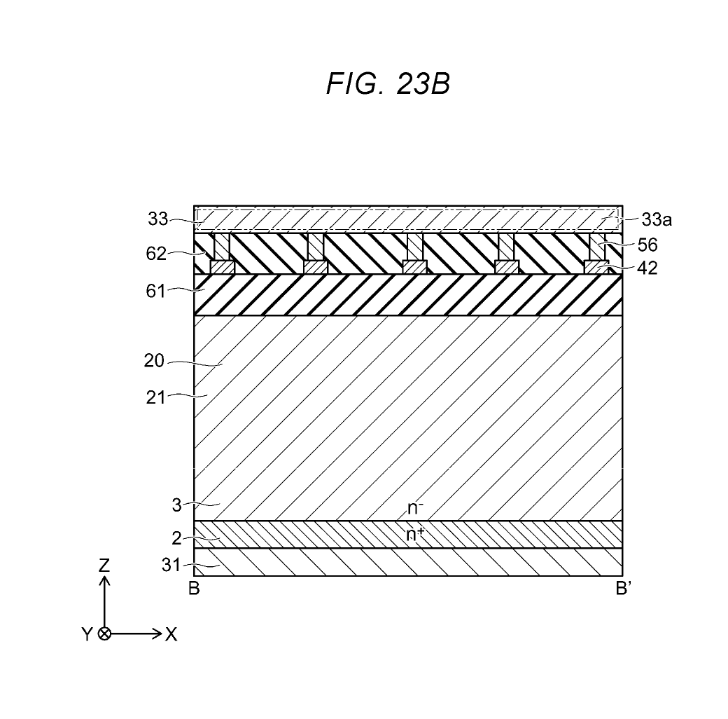

FIG. 23A is a sectional view taken along the line A-A′ in FIG. 22 and FIG. 23B is a sectional view taken along the line B-B′ in FIG. 22.

In FIG. 21, the source pads 32 and the gate wiring 33 are indicated by dotted lines.

In FIG. 22, the source pads 32, the gate wiring 33, and the insulation layers 61 and 62 are not illustrated and the metal layers 42 and 43 are indicated by dotted lines.

In the semiconductor device 310, as illustrated in FIG. 21, the metal layers 42 and 43 extend in the Y direction below the source pads 32. The metal layers 42 and 43 are alternately spaced apart in the X direction. End portions of the metal layers 42 in the Y direction are formed below the gate wiring 33.

As illustrated in FIG. 22, the gate electrodes 20 extending in the Y direction are formed below the metal layers 42.

As illustrated in FIG. 23A, each metal layer 42 is formed above a gate electrode 20, and each gate electrode 20 is connected to a metal layer 42 by the plug 55.

Each metal layer 43 is formed above the n⁺ type semiconductor region 5, and the n⁺ type semiconductor region 5 and the metal layer 43 are connected by the plug 57a. The metal layer 43 is connected to the source pad 32 by the plug 57b.

As illustrated in FIG. 23B, a portion of the metal layer 42 is formed below the first extension portion 33a, and the metal layer 42 and the first extension portion 33a are connected by the plug 56.

Similarly, another portion of the metal layer 42 is also formed below the second extension portion 33b, and the second extension portion 33b and the metal layer 42 are connected by the plug 56.

According to the present modification example, the first extension portion 33a and the second extension portion 33b are connected by the metal layer 42 and the gate electrode 20 is formed below the metal layer 42. Therefore, even in the present modification example, it is possible to decrease the difference in the gate delay time in the semiconductor device as in the semiconductor device 300.

### Second Modification Example

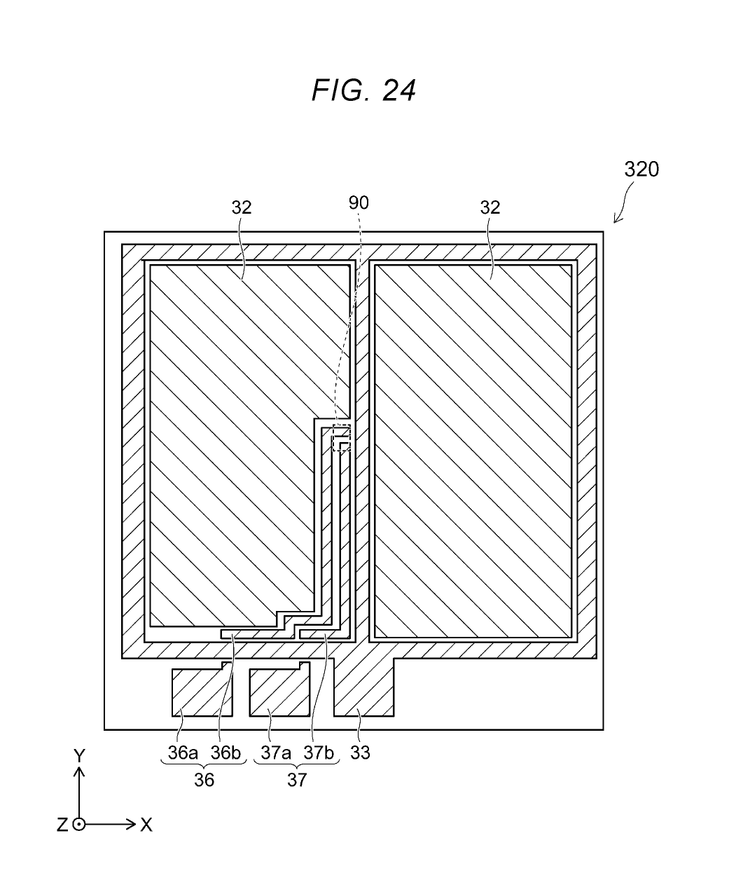

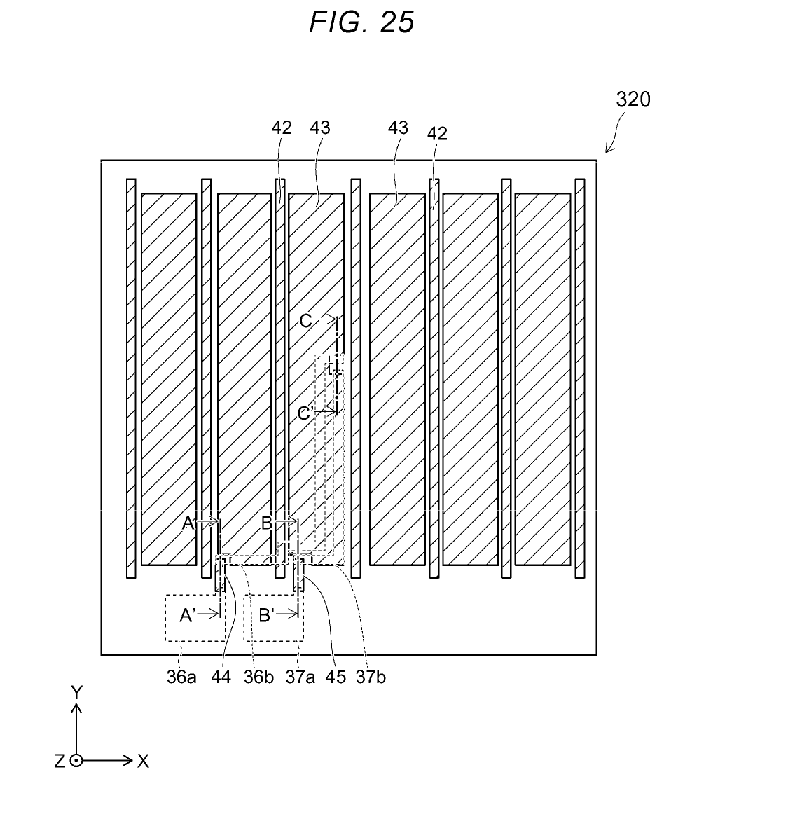

FIGS. 24 and 25 are plan views illustrating a semiconductor device 320 according to a second modification example of the third embodiment.

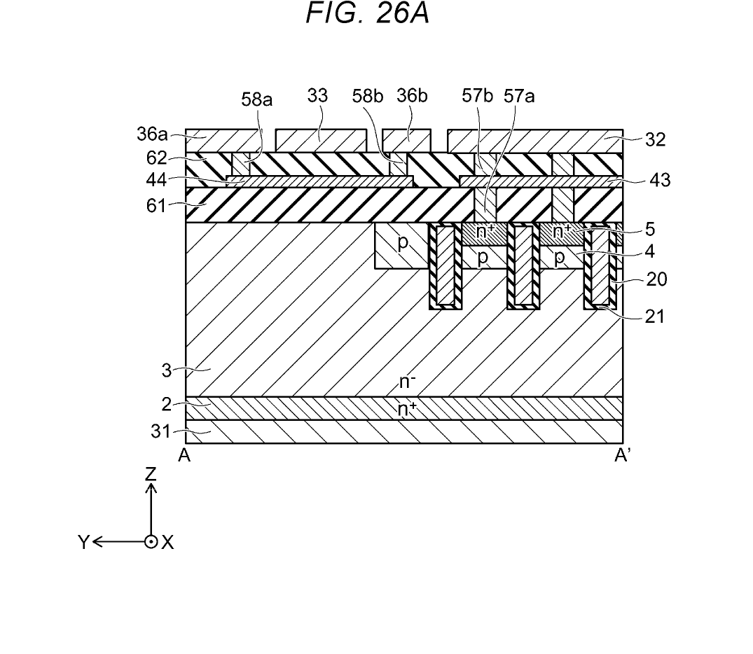

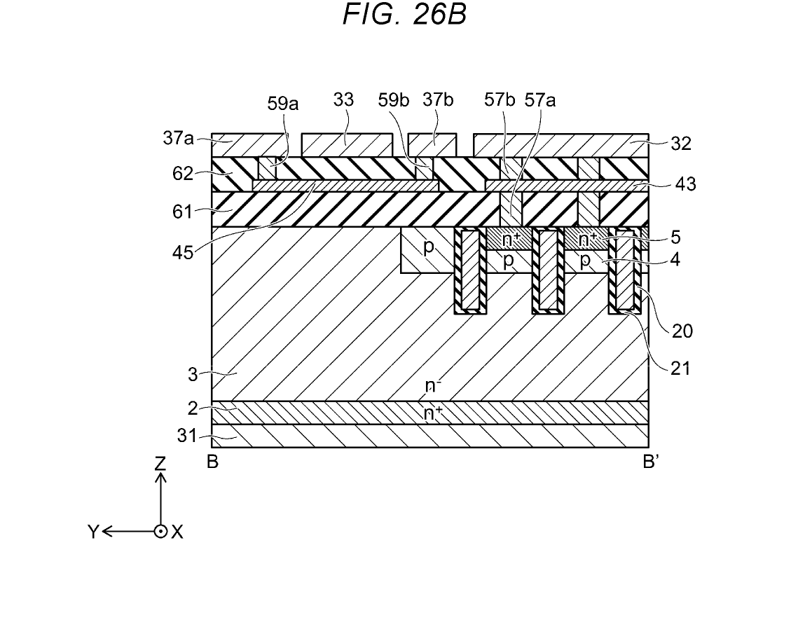

FIG. 26A is a sectional view taken along the line A-A′ in FIG. 25 and FIG. 26B is a sectional view taken along the line B-B′ in FIG. 25.

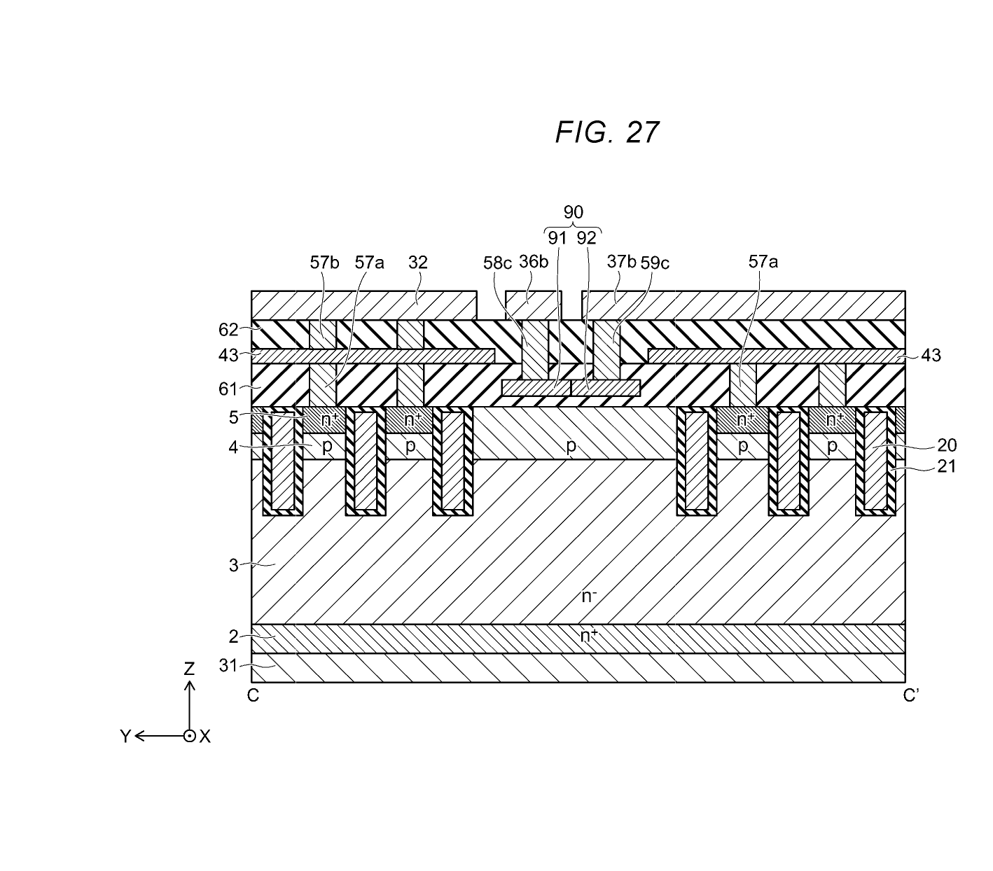

FIG. 27 is a sectional view taken along the line C-C′ in FIG. 25.

In FIG. 25, the source pads 32 and the gate wiring 33 are not illustrated, and an anode pad 36 and a cathode pad 37 are indicated by dotted lines.

The semiconductor device 320 is different from the semiconductor device 300 in that the anode pad 36, the cathode pad 37, a metal layer 44, a metal layer 45 and a diode 90 are further included.

As illustrated in FIG. 24, the source pads 32, the gate wiring 33, the anode pad 36, and the cathode pad 37 are formed on the upper surface of the semiconductor device 320 spaced apart from each other.

The anode pad 36 includes a pad portion 36a and a wiring portion 36b.

The cathode pad 37 includes a pad portion 37a and a wiring portion 37b.

An external circuit is connected to the pad portions 36a and 37a.

The wiring portions 36b and 37b are formed in regions surrounded by the gate wiring 33 and the pad portions 36a and 37a are formed in regions outside the gate wiring 33.

A diode 90 that measures temperature of the semiconductor device 320 is formed between the wirings 36b and 37b.

As illustrated in FIGS. 25 and 26, the metal layers 44 and 45 are formed below the gate wiring 33.

A portion of the metal layer 44 is connected to the pad portion 36a and another portion of the metal layer 44 is connected to the wiring portion 36b.

A portion of the metal layer 45 is connected to the pad portion 37a and another portion of the metal layer 45 is connected to the wiring portion 37b.

As illustrated in FIG. 26A, the metal layer 44 is connected to the pad portion 36a by a plug 58a and is connected to the wiring portion 36b by a plug 58b.

As illustrated in FIG. 26B, the metal layer 45 is connected to the pad portion 37a by a plug 59a and is connected to the wiring portion 37b by a plug 59b.

As illustrated in FIG. 27, the diode 90 is formed in the insulation layer 61. The diode 90 includes a p type semiconductor portion 91 and an n type semiconductor portion 92 contacting to each other.

A plug 58c is formed in the insulation layers 61 and 62, and the p type semiconductor portion 91 is connected to the wiring portion 36b by the plug 58c.

A plug 59c is formed in the insulation layers 61 and 62, and the n type semiconductor portion 92 is connected to the wiring portion 37b by the plug 59c.

A current-voltage property of the diode depends on temperature. Therefore, by applying a voltage between the anode pad 36 and the cathode pad 37 and flowing a current to the diode 90, it is possible to measure the temperature of the semiconductor device 320.

Here, examples of the materials of the constituent elements will be described.

The anode pad 36, the cathode pad 37, and the metal layers 42 to 45 are metal layers that contain a metal material such as aluminum.

The plugs 55 to 59 contain a metal material such as titanium or tungsten.

The p type semiconductor portion 91 and the n type semiconductor portion 92 are, for example, polysilicon that contains each conductivity type impurity.

For the other constituent elements, the materials described in the first embodiment can be used.

By forming the diode 90 in an element region in which the gate electrode 20, the n⁺ type semiconductor region 5, the source pad 32, or the like is formed, it is possible to measure the temperature of the semiconductor device more accurately.

In the present embodiment, the pad portion 36a and the wiring portion 36b are connected via the metal layer 44 and the plugs 58a and 58b. The pad portion 37a and the wiring portion 37b are connected via the metal layer 45 and the plugs 59a and 59b. The diode 90 is connected between the wiring portions 36b and 37b.

In this way, when the diode 90 is connected between the pad portions 36a an 37a through the metal layers 44 and 45 formed below the gate wiring 33, it is not necessary to form the gate wiring 33 turning around the regions in which the anode pad 36, the cathode pad 37, and the diode 90 are formed. Therefore, according to the present embodiment, it is possible to form the diode 90 for temperature measurement in the element region of the semiconductor device while suppressing an increase in the electric resistance in the gate wiring 33 and suppressing an increase in the difference in the gate delay time.

In the present embodiment, as illustrated in FIG. 25, the metal layer 43 is formed below the wiring portions 36b and 37b. As illustrated in FIGS. 26A and 26B, the metal layer 43 is connected to the n⁺ type semiconductor region 5 by the plug 57a and is connected to the source pad 32 by the plug 57b. That is, according to the present embodiment, by forming the metal layer 43 connected to the source pad 32 between the insulation layers 61 and 62, it is possible to also use the regions below the wiring portions 36b and 37b as element regions.

Therefore, according to the present embodiment, it is possible to form the diode 90 in the element region of the semiconductor device while suppressing a reduction in the area of the element region.

The semiconductor device according to the third embodiment is a MOSFET, as described above. However, the present embodiment can also be applied to semiconductor devices other than a MOSFET, including the first and second modification examples. For example, when the third embodiment is applied to an IGBT, a p⁺ type semiconductor region is formed between the n⁺ type semiconductor region 2 and the drain electrode 31 or is formed instead of the n⁺ type semiconductor region 2.

In the embodiments described above, a relative magnitude of an impurity concentration between semiconductor regions can be confirmed using, for example, a scanning capacitance microscope (SCM). A carrier concentration of each semiconductor region can be regarded to be the same as the impurity concentration activated in each semiconductor region. Accordingly, a relative magnitude of a carrier concentration between the semiconductor regions can also be confirmed using an SCM.

An impurity concentration of each semiconductor region can also be measured using, for example, secondary ion mass spectrometry (SIMS).

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The specific configurations of the elements, for example, the p⁺ type semiconductor region 1, the n⁺ type semiconductor region 2, the n⁻ type semiconductor region 3, the p type semiconductor region 4, the n⁺ type semiconductor region 5, the p⁺ type semiconductor region 6, the p type semiconductor region 7, the n⁺ type semiconductor region 8, the p⁺ type semiconductor region 9, the p⁺ type semiconductor region 10, the p type guard ring region 12, the p⁺ type semiconductor region 13, the gate electrode 20, the gate insulation layer 21, the electrode 31, the pad 32, the gate wiring 33, the sense pad 34, the anode pad 36, the cathode pad 37, the metal layers 41 to 45, the metal layer 47, the plugs 51 to 59, the insulation layer 61, the insulation layer 62, the FP electrode 70, the insulation layer 71, the current detection unit 80, the gate driving circuit 81, and the diode 90 included in the embodiments, can be appropriately selected from known technologies by those skilled in the art. The accompanying claims and their equivalents are intended to cover such forms or modifications as would fall within the scope and spirit of the inventions.

What is claimed is:

1. A semiconductor device comprising:
a first-conductivity type first semiconductor region;
a gate electrode extending inwardly of the first semiconductor region;
a gate insulation layer interposed between the gate electrode and the first semiconductor region;
a second-conductivity type second semiconductor region on the first semiconductor region;
a first-conductivity type third semiconductor region on selected portions of second semiconductor region;
a second-conductivity type fourth semiconductor region on the first semiconductor region and spaced from the second semiconductor region;
a first-conductivity type fifth semiconductor region on the fourth semiconductor region;
a first insulation layer on the third and fifth semiconductor regions and extending over the gate electrode;
a first electrode on the first insulation layer; and
a first insulation portion extending between the second and fourth semiconductor regions.

2. The semiconductor device according to claim 1, further comprising:
a first connection portion extending through the first insulation layer and connecting the first electrode and the fifth semiconductor region;
a second insulation layer on the first electrode;
a second electrode on the second insulation layer; and
a second connection portion extending through the first insulation layer and the second insulation layer and connecting the second electrode and the third semiconductor region.

3. The semiconductor device according to claim 2,
wherein a portion of the first electrode is located above the third semiconductor region,
the first electrode has a first opening, and
the second connection portion extends through the first opening.

4. The semiconductor device according to claim 2, further comprising:
a second-conductivity type sixth semiconductor region on the first semiconductor region;
a first-conductivity type seventh semiconductor region on selected portions of the sixth semiconductor region; and
a third connection portion extending through the first insulation layer and the second insulation layer, and connecting the second electrode and the seventh semiconductor region.

5. The semiconductor device according to claim 4, wherein
a portion of the first metal layer is located over the seventh semiconductor region;
the first electrode has a second opening; and
the third connection portion extends through the second opening.

6. The semiconductor device of claim 4, further comprising:
a portion in which the first electrode is not located between the second electrode and the first insulation layer, wherein
the third connection portion extends through the first insulation layer and the second insulation layer to connect the portion of the second electrode not having the first electrode located between the second electrode and the first insulation layer with the seventh semiconductor region.

7. The semiconductor device of claim 3, further comprising:
a field plate electrode extending inwardly of the first semiconductor region and extending therefrom toward the second electrode; and
a fourth connection portion connecting the field plate electrode and the second electrode.

8. The semiconductor device of claim 3, wherein the first and second electrodes are metallic.

9. The semiconductor device of claim 3, further comprising a third electrode, wherein
the first semiconductor region is interposed between the first electrode and the third electrode; and
the first electrode is interposed between the third electrode and at least portions of the second electrode.

10. A semiconductor device comprising:
a first electrode;
a first-conductivity type first semiconductor region on the first electrode;
a second-conductivity type second semiconductor region on the first semiconductor region;
a second-conductivity type third semiconductor region on the second semiconductor region and having a second conductivity type impurity concentration higher than the second semiconductor region;
a second-conductivity type fourth semiconductor region on second semiconductor region and spaced from the third semiconductor region and having a second-conductivity type impurity concentration higher than the second semiconductor region;
a first insulation layer on the third semiconductor region and the fourth semiconductor region;
a first metal layer on the first insulation layer;
a first connection portion extending through the first insulation layer and connecting the first metal layer and the fourth semiconductor region;
a second insulation layer on the first metal layer;
a second metal layer on the second insulation layer; and
a second connection portion extending through the first insulation layer and the second insulation layer and connecting the second metal layer and the third semiconductor region.

11. The semiconductor device according to claim 10, further comprising:
a plurality of fourth semiconductor regions;
a plurality of first connection portions; and
a plurality of first metal layers,
wherein the plurality of fourth semiconductor regions are located around and spaced from the third semiconductor region and spaced from each other, and
the plurality of first connection portions connect the plurality of fourth semiconductor regions to the plurality of first metal layers, respectively.

12. The semiconductor device according to claim 10, further comprising:
a plurality of third semiconductor regions;
a plurality of second connection portions, wherein
the plurality of second connection portions respectively connect the plurality of third semiconductor regions to the second metal layer.

13. The device of claim 11, further comprising a plurality of second conductivity type fifth semiconductor regions on the first semiconductor region, the fifth semiconductor regions surrounding and spaced from the second semiconductor region.

14. The semiconductor device according to claim 13, wherein the first metal layers extend over the fifth semiconductor regions.

15. A semiconductor device comprising:
a first-conductivity type first semiconductor region;
a second-conductivity type second semiconductor region on the first semiconductor region;
a first-conductivity type third semiconductor region on selected portions of the second semiconductor region;
a gate electrode extending from within the first semiconductor region to be adjacent to the second semiconductor region and the third semiconductor region;
a gate insulation layer interposed between the gate electrode and the first, second and third semiconductor regions;
a first insulation layer on the third semiconductor region and over the gate electrode;
a first metal layer on the first insulation layer;
a first connection portion extending through the first insulation layer and connecting the first metal layer and the gate electrode;
a second metal layer on the first insulation layer spaced from the first metal layer;
a second insulation layer on the first metal layer and the second metal layer;
a third metal layer on the second insulation layer;
a second connection portion extending through the first insulation layer connecting the second metal layer and the third semiconductor region; and
a third connection portion extending through the second insulation layer and connecting the second metal layer and the third metal layer.

16. The semiconductor device according to claim 15, further comprising:
a second conductivity type fourth semiconductor region on the first semiconductor region and adjacent to the gate electrode; and
a fourth connection portion extending through the first insulation layer and connecting the second metal layer and the fourth semiconductor region.

17. The semiconductor device of claim 15, further comprising:
a fourth metal layer on the second insulation layer and spaced from the third metal layer, a portion of the fourth metal layer overlying a portion of an end of the first metal layer; and
a fourth connection portion layer extending through the second insulation layer and connecting the fourth metal layer and the underlying portion of the first metal layer.

18. The semiconductor device of claim 17, wherein the fourth metal layer surrounds, and bisects, the third metal layer.

19. The semiconductor device according to claim 15, wherein the gate electrode crosses beneath the first metal layer and the second metal layer.

20. The semiconductor device according to claim 15, wherein
the first metal layer is longer in a first direction than the length of the second metal layer in the first direction; and
the second metal layer is wider in a second direction crossing the first direction than the width of the first metal layer in the second direction.
